(19) United States
(12) Patent Application Publication
(10) Pub. No.: US 2024/0310412 A1
(43) Pub. Date: Sep. 19, 2024

(54) UNIVERSAL PROBE CARD AND TESTING METHOD

(71) Applicant: PANJIT INTERNATIONAL INC., Kaohsiung City (TW)

(72) Inventors: CHUNG-HSIUNG HO, Kaohsiung City (TW); CHIA-WEI CHEN, Kaohsiung City (TW); PING-JUI HSIEH, Kaohsiung City (TW)

(21) Appl. No.: 18/385,417

(22) Filed: Oct. 31, 2023

(30) Foreign Application Priority Data
Mar. 17, 2023 (TW) 112110003

(51) Int. Cl. G01R 1/073; G01R 1/067; G01R 31/28

(52) U.S. Cl. CPC G01R 1/07371; G01R 1/06722; G01R 31/2831

(57) ABSTRACT

An universal probe card and a testing method are disclosed. The universal probe card includes a plurality of probes. The probes are configured to contact and test a plurality of different patterns to be tested. Each of the plurality of different patterns to be tested includes a plurality of portions to be tested. A pitch between the plurality of probes is a greatest common factor of pitches between the plurality of portions to be tested in the plurality of different patterns to be tested.

### BACKGROUND

### 1. Field of the Disclosure

The disclosure relates to an universal probe card and a testing method, in particular to an universal probe card with a plurality of probes, and a testing method.

### 2. Description of the Related Art

The current electrical testing methods for electronic elements (such as semiconductor chips or semiconductor dice) are roughly classified into two types as follows. The first testing method is to place a plurality of electronic elements on a socket by a pick-and-place method and then test the electronic elements by using a probe card. An existing probe card can test a plurality of electronic elements at once, and if the number of probes on the probe card is enough, the probe card can also achieve a function of current distribution. However, the conventional probe card is usually dedicated. That is, the probe card is designed according to the product appearance and electrical property of the electronic element, and one type of electronic elements is matched with one dedicated probe card. If the size of the electronic elements is changed or the pitches between bonding pads of the electronic elements are different, the original probe card can only be retained and cannot be used any more. That is, after the probe card is manufactured, if the electronic element is modified, the probe card cannot be changed accordingly. In other words, electronic elements to be tested with different sizes need to be matched with probe cards having different specifications. Therefore, the cost of testing process is greatly increased, especially when the electronic elements have high variation.

The second testing method is to pour electronic elements to be tested into a bowl feeder and then perform an electrical test by using a socket. By this method, only one electronic element can be tested at a time, the units per hour (UPH) of this method is lower than the UPH of the first method. In addition, the tested electronic elements don't have traceability.

### SUMMARY

According to one embodiment of the disclosure, an universal probe card includes a plurality of probes. The probes are configured to contact and test a plurality of different patterns to be tested. Each of the plurality of different patterns to be tested includes a plurality of portions to be tested. A pitch between the plurality of probes is a greatest common factor of pitches between the plurality of portions to be tested in the plurality of different patterns to be tested.

According to one embodiment of the disclosure, an universal probe card is configured to test a plurality of different elements to be tested. The universal probe card includes a probe holder. The probe holder defines a plurality of accommodating holes. A pitch between the plurality of accommodating holes is a greatest common factor of pitches between a plurality of portions to be tested of the plurality of different elements to be tested.

According to one embodiment of the disclosure, a testing method includes: providing a plurality of elements to be tested, wherein the plurality of elements to be tested have a plurality of different patterns to be tested, and each of the plurality of patterns to be tested has a plurality of portions to be tested; providing an universal probe card, wherein the universal probe card comprises a probe holder and a plurality of probes, the probe holder defines a plurality of accommodating holes, a pitch between the plurality of accommodating holes is determined by the pitches between the plurality of portions to be tested in the plurality of different patterns to be tested, and at least one group of the plurality of probes are respectively located in at least one group of the plurality of accommodating holes; and contacting at least one of the plurality of elements to be tested by using the at least one group of the plurality of probes.

### BRIEF DESCRIPTION OF THE DRAWINGS

Various aspects of the disclosure are best understood from the following description when read with the accompanying drawings. It should be noted that, the various features are not drawn to scale in accordance with standard practice in the industry.

FIG. 1 is an exploded perspective view of an universal probe card according to one embodiment of the disclosure.

FIG. 2 is a partially enlarged cross-sectional view of the assembled universal probe card of FIG. 1.

FIG. 3 is a schematic diagram showing probes separated from a probe holder of FIG. 2.

FIG. 4 is a schematic top view showing a combination of the probe holder and the probes of the universal probe card of FIG. 1.

FIG. 4A is a partially enlarged view showing the combination of the probe holder and the probes of the universal probe card of FIG. 4.

FIG. 5 is a perspective view showing the use state of the universal probe card of FIG. 1 to FIG. 4A, wherein the universal probe card is located right above a plurality of elements to be tested.

FIG. 5A is a top view of FIG. 5.

FIG. 5B is a cross-sectional view along line I-I of FIG. 5A.

FIG. 5C is a top view of a single element to be tested.

FIG. 5D is a cross-sectional view showing the use state of the universal probe card of FIG. 5B, wherein the universal probe card (including the combination of the probe holder and the probes) and the elements to be tested are in contact with each other.

FIG. 5E is a perspective view showing the use state of the universal probe card of FIG. 1 to FIG. 4A, wherein the universal probe card is located right above an apparatus to be tested.

FIG. 5F is a top view of FIG. 5E.

FIG. 5G is a cross-sectional view along line I′-I′ of FIG. 5F.

FIG. 5H is a partially enlarged view of the apparatus to be tested of FIG. 5E.

FIG. 6 is a perspective view showing the use state of a universal probe card according to one embodiment of the disclosure, wherein the universal probe card is located right above a plurality of elements to be tested.

FIG. 6A is a top view of FIG. 6.

FIG. 6B is a cross-sectional view along line II-II of FIG. 6A.

FIG. 6C is a top view of a single element to be tested.

FIG. 6D is a cross-sectional view showing the use state of the universal probe card of FIG. 6B, wherein the universal probe card (including the combination of the probe holder and the probes) is in contact with the elements to be tested.

FIG. 7 is a perspective view showing the use state of a universal probe card according to one embodiment of the disclosure, wherein the universal probe card is located right above a plurality of elements to be tested.

FIG. 7A is a top view of FIG. 7.

FIG. 7B is a cross-sectional view along line III-III of FIG. 7A.

FIG. 7C is a top view of a single element to be tested.

FIG. 7D is a cross-sectional view showing the use state of the universal probe card of FIG. 7B, wherein the universal probe card (including the combination of the probe holder and the probes) is in contact with the elements to be tested.

FIG. 8 is a cross-sectional view showing the use state of the universal probe card according to one embodiment of the disclosure, wherein the universal probe card is located right above the plurality of elements to be tested.

FIG. 8A is a cross-sectional view showing the use state of the universal probe card of FIG. 8, wherein the universal probe card is in contact with the elements to be tested.

FIG. 9 is a schematic top view of a combination of a probe holder and a plurality of probes of a universal probe card according to one embodiment of the disclosure.

FIG. 9A is a partially enlarged view showing the combination of the probe holder and the probes of the universal probe card of FIG. 9.

FIG. 10 is a schematic top view showing the use state of the universal probe card of FIG. 9.

FIG. 11 is a schematic top view showing the use state of the universal probe card of FIG. 9.

FIG. 12 is a schematic top view showing the use state of the universal probe card of FIG. 9.

### DETAILED DESCRIPTION

The components, values, operations, materials and configurations in the following disclosure are merely embodiments or examples and are not intended to be limiting. For example, a first element being formed over or on a second element may include different implementations. The first element and the second element may be in direct contact. Alternatively, the first element and the second element may not be in direct contact, and an additional element between the first element and the second element may be included.

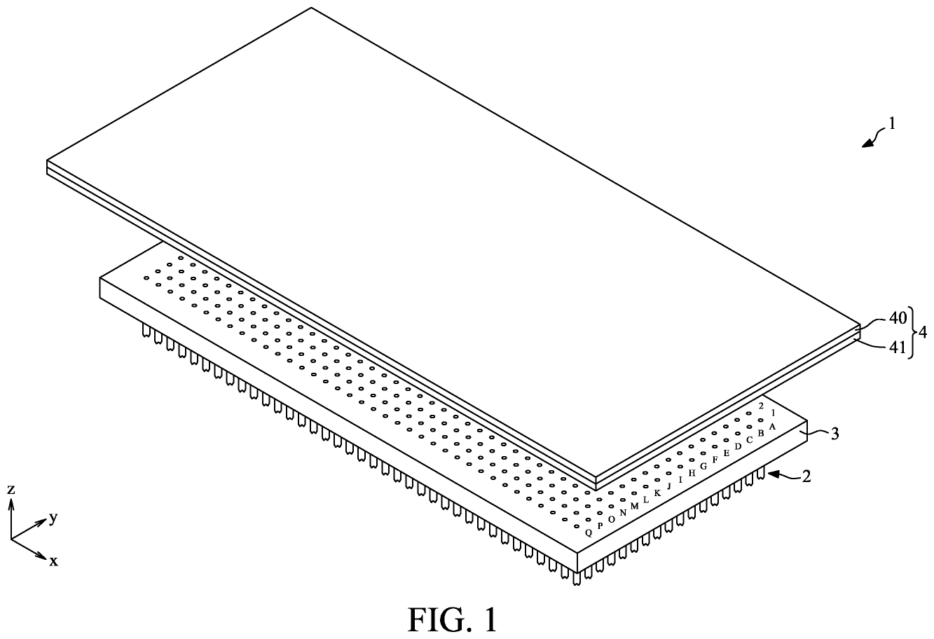

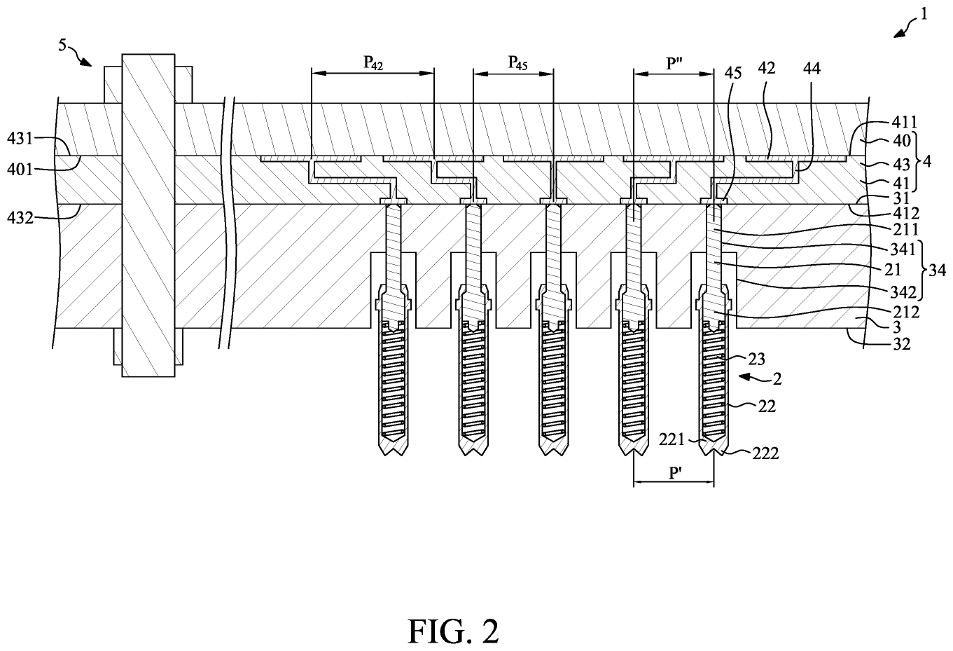

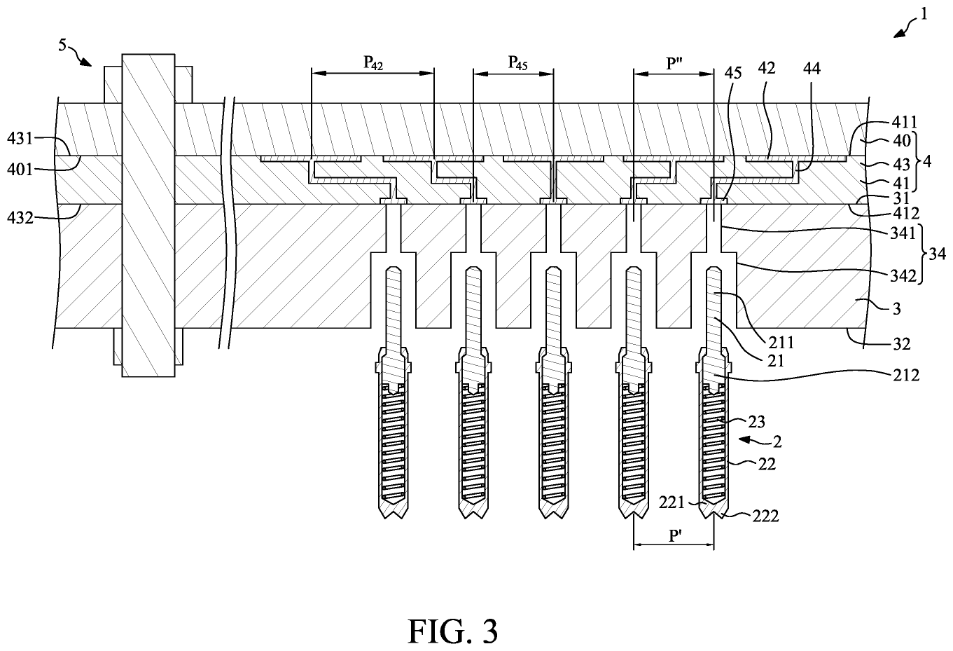

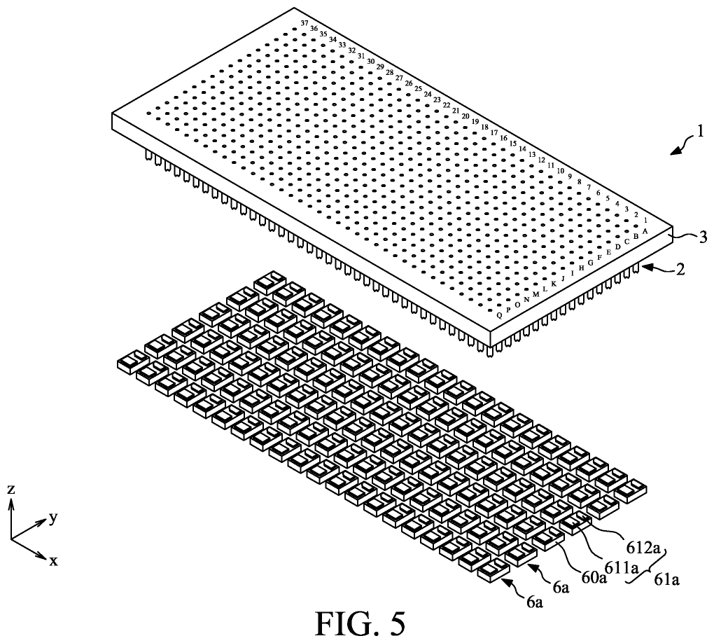

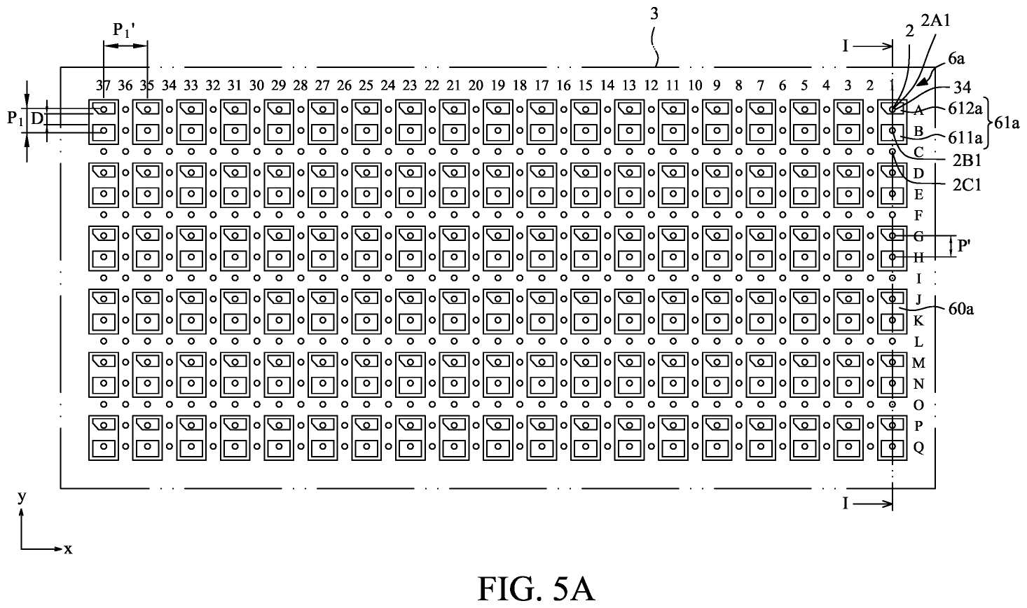

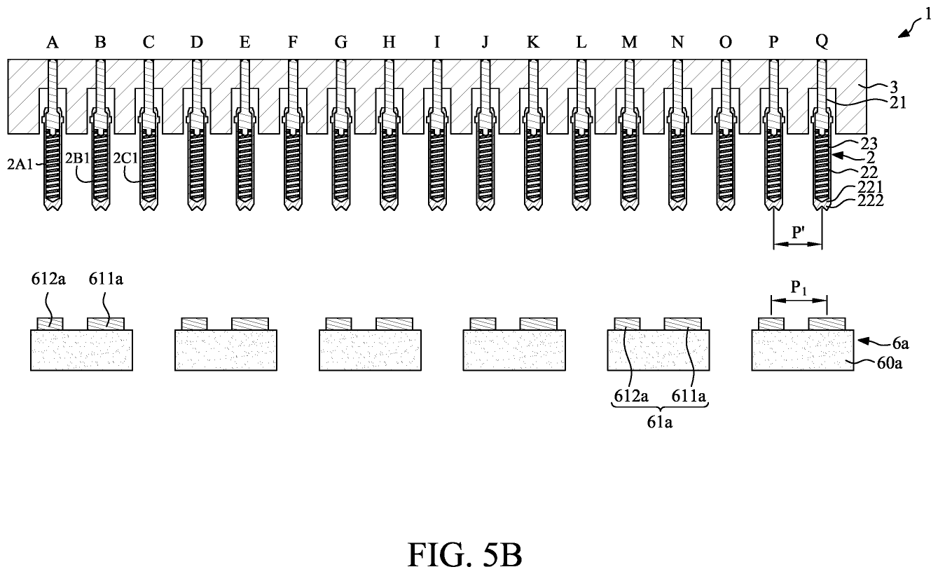

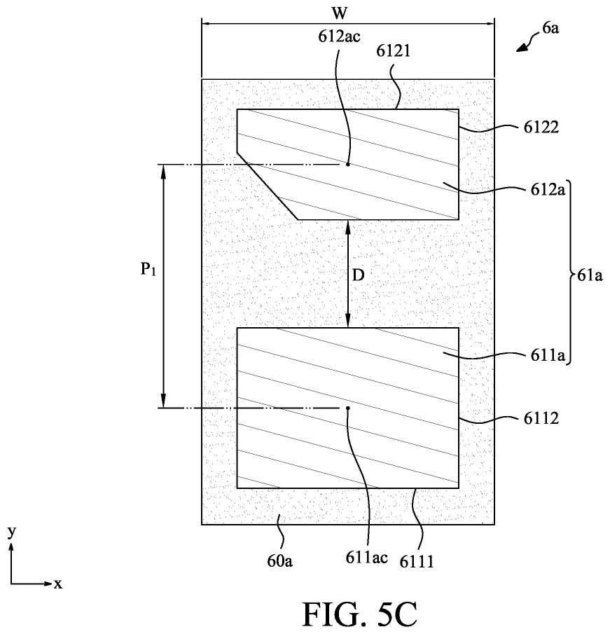

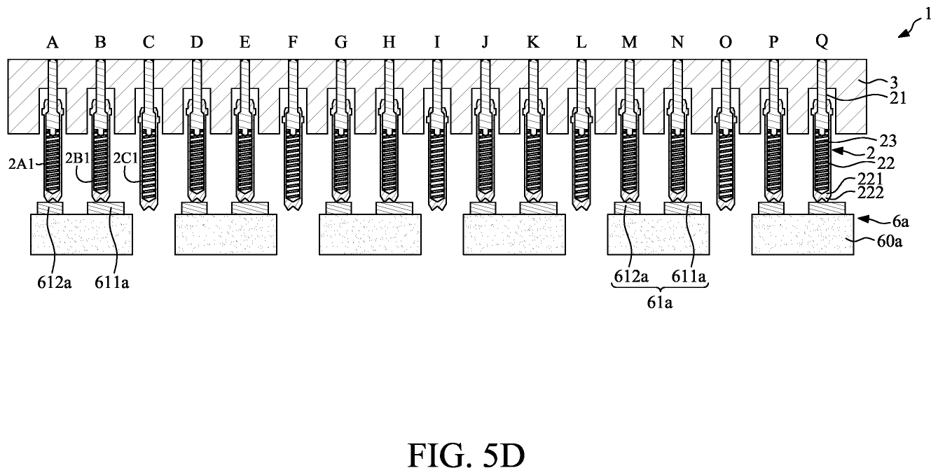

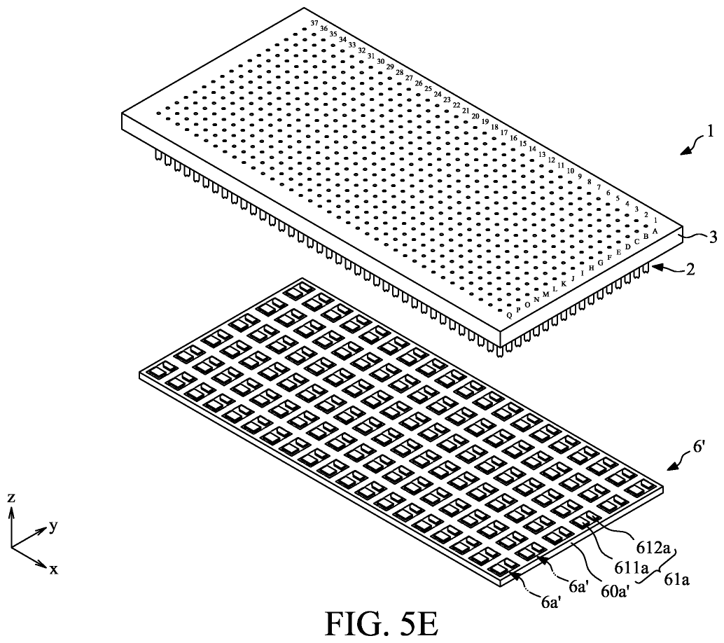

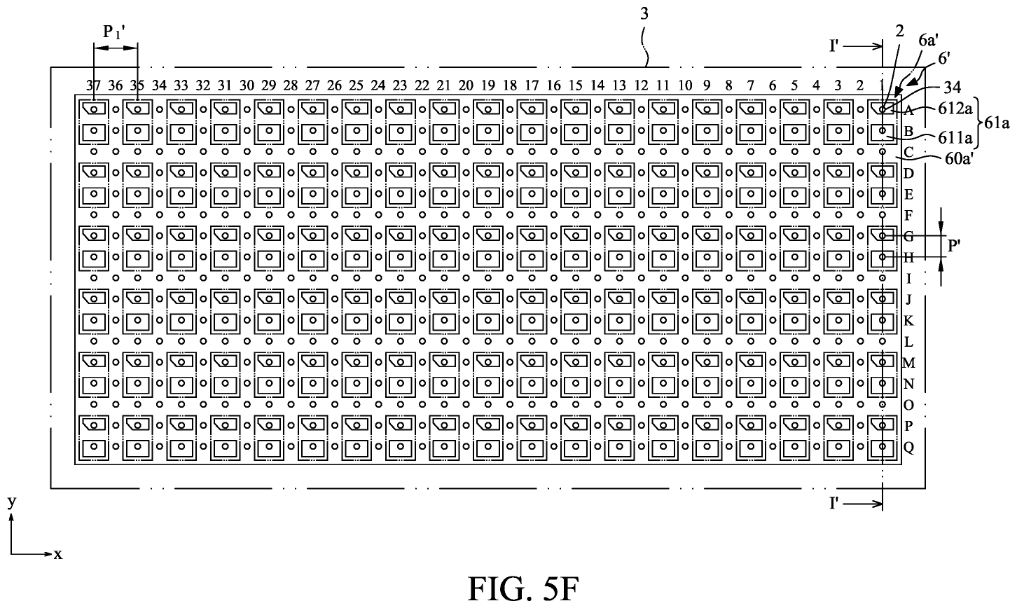

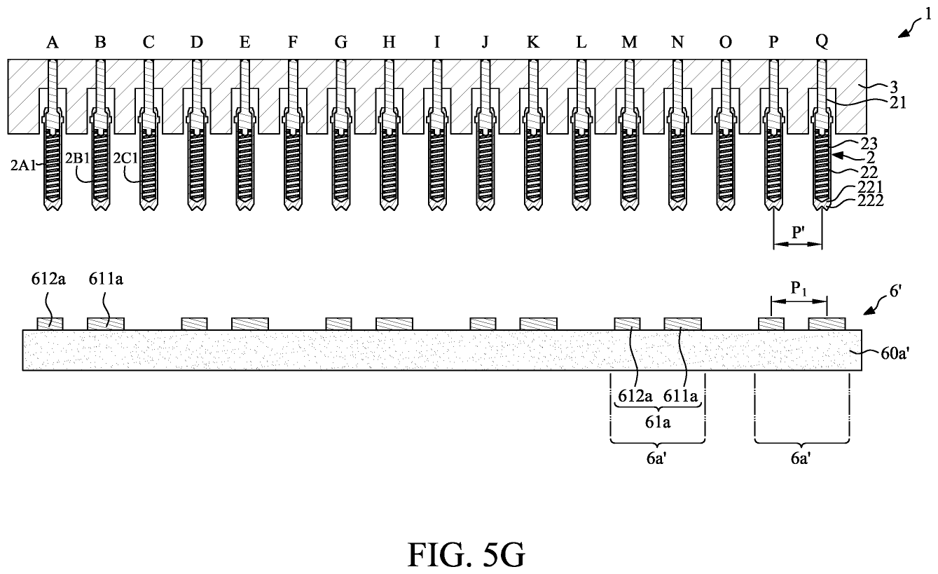

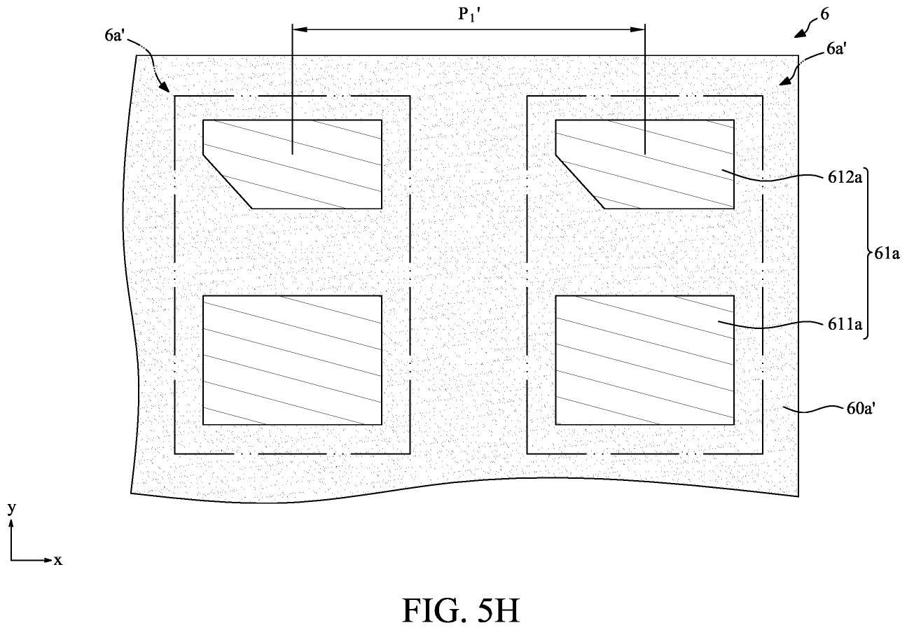

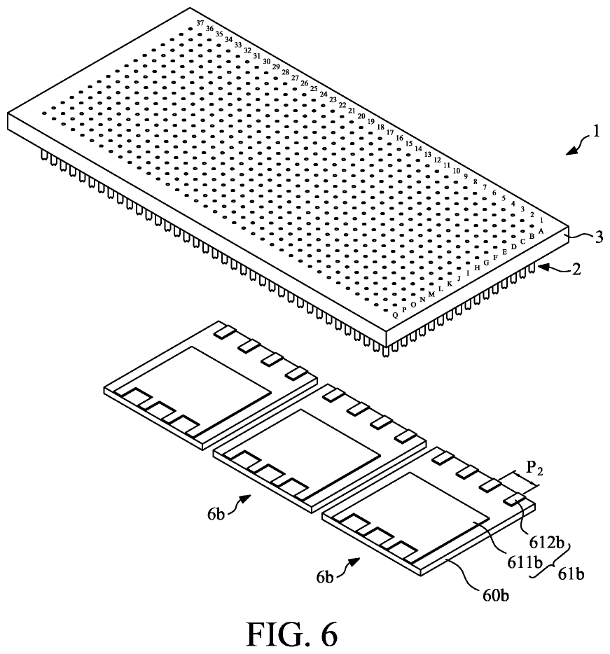

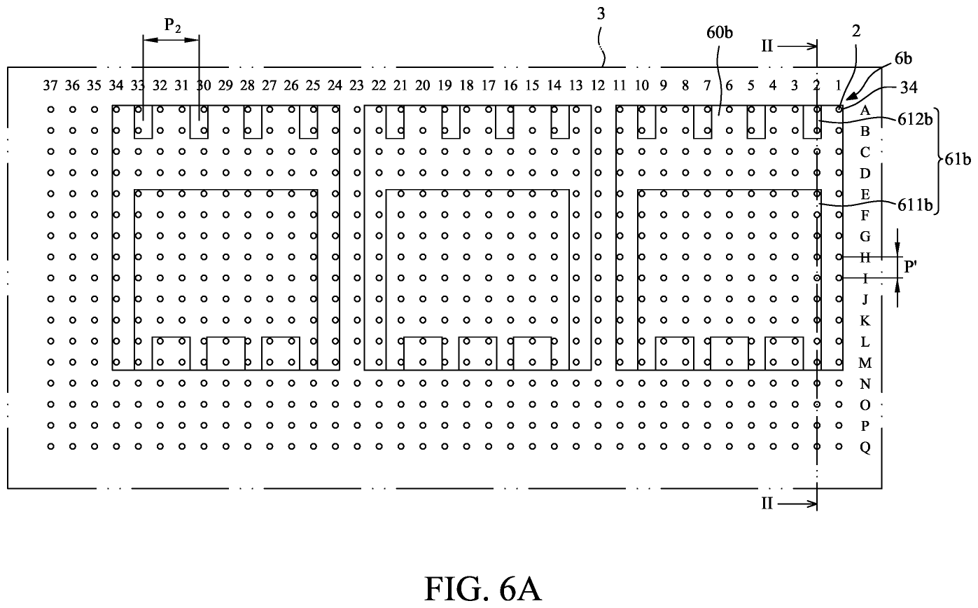

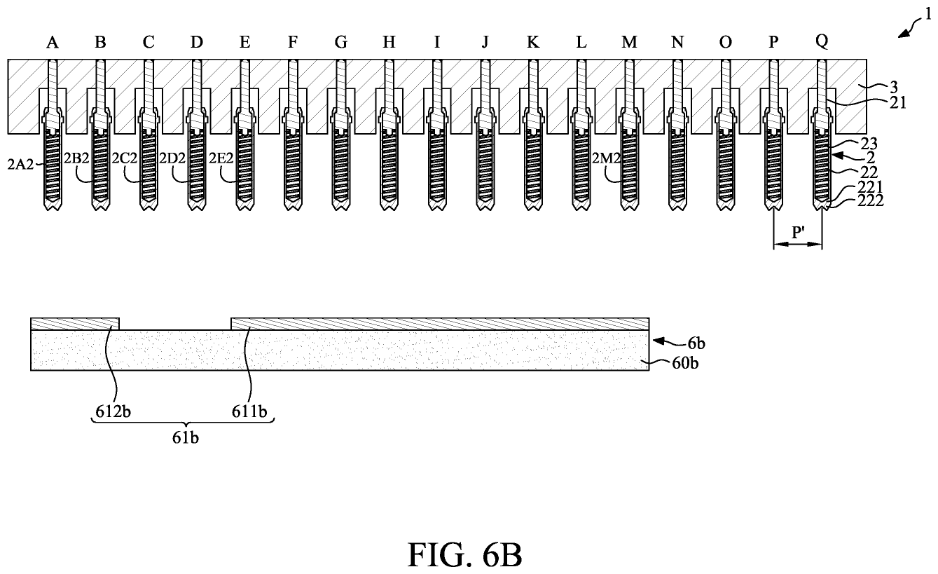

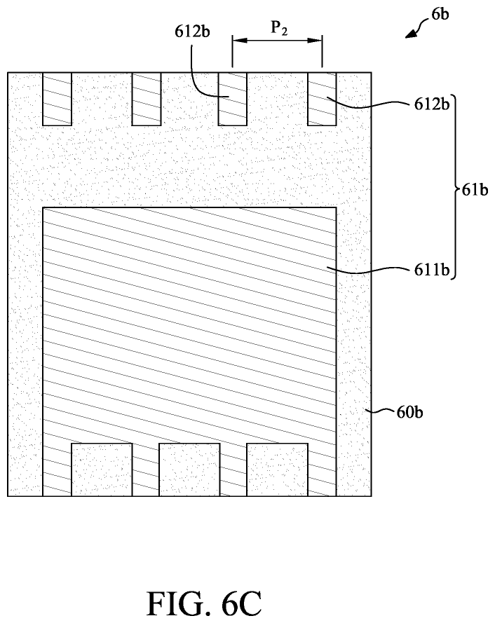

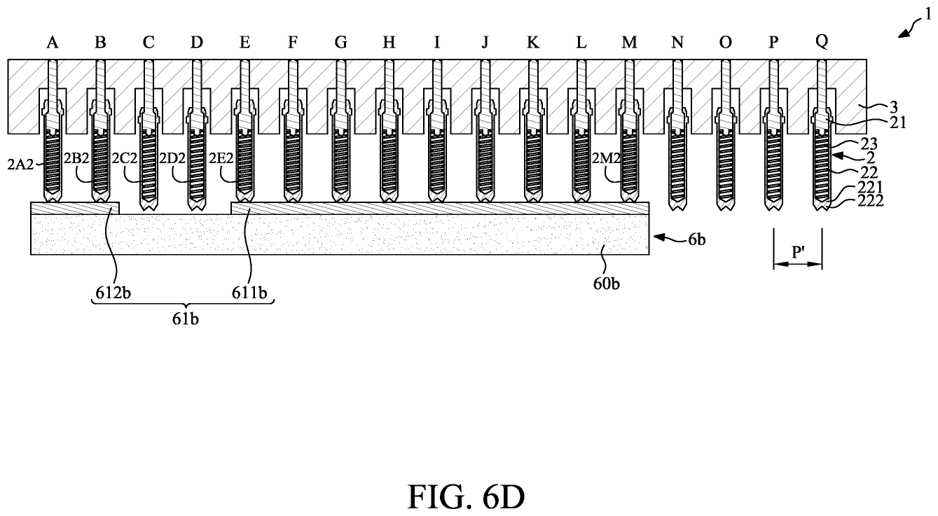

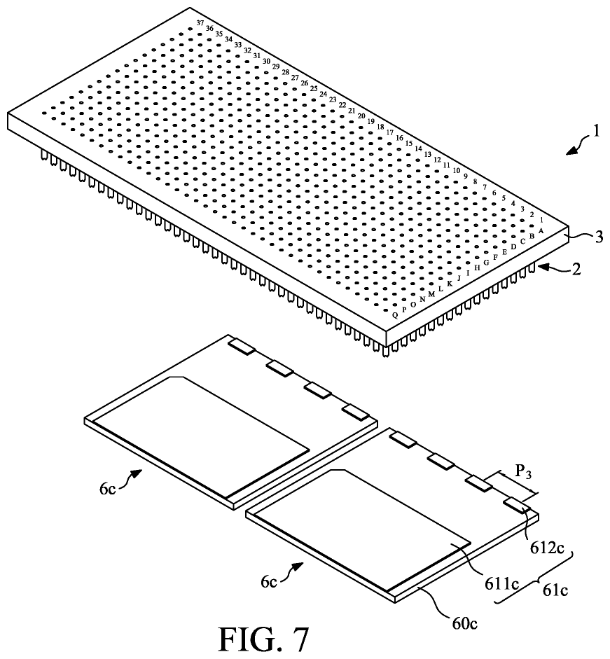

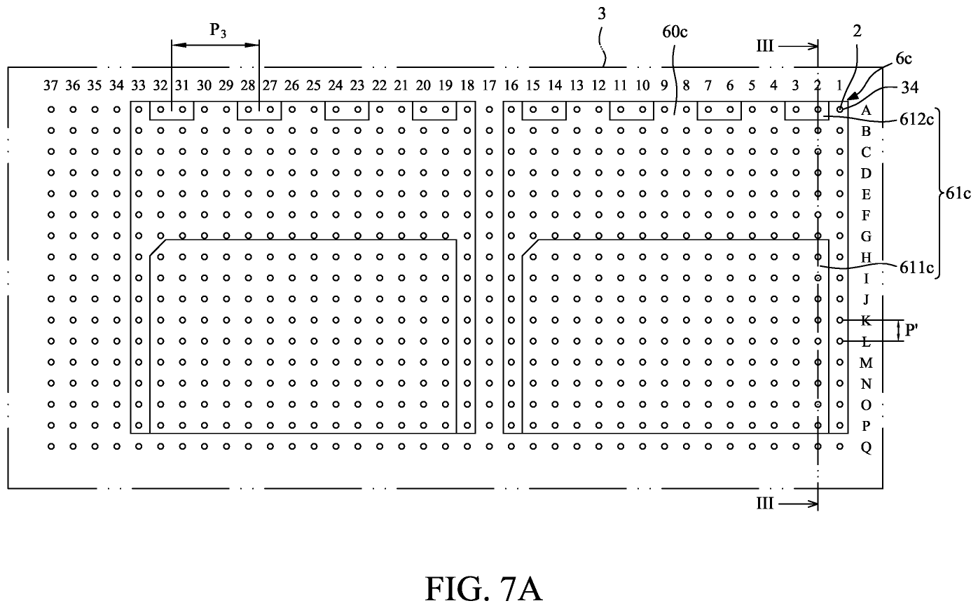

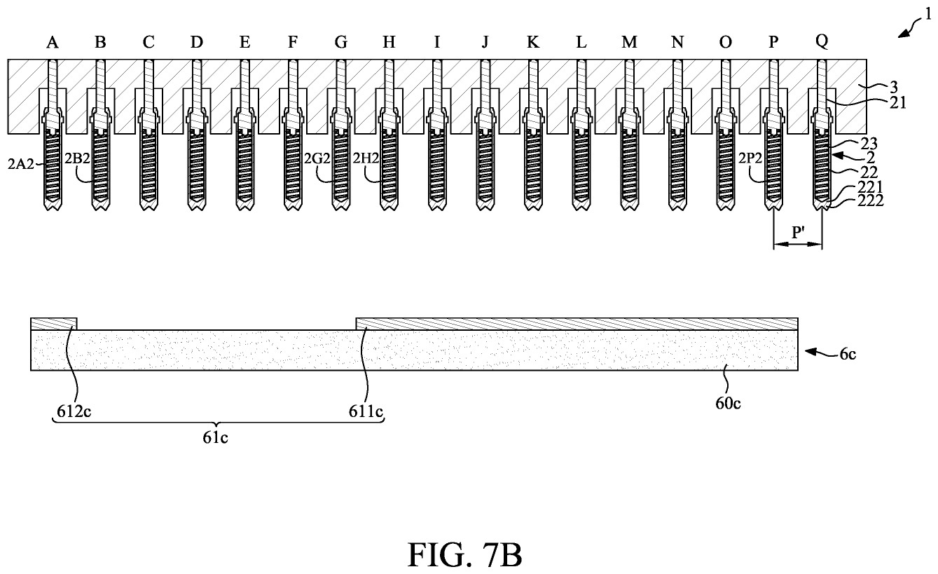

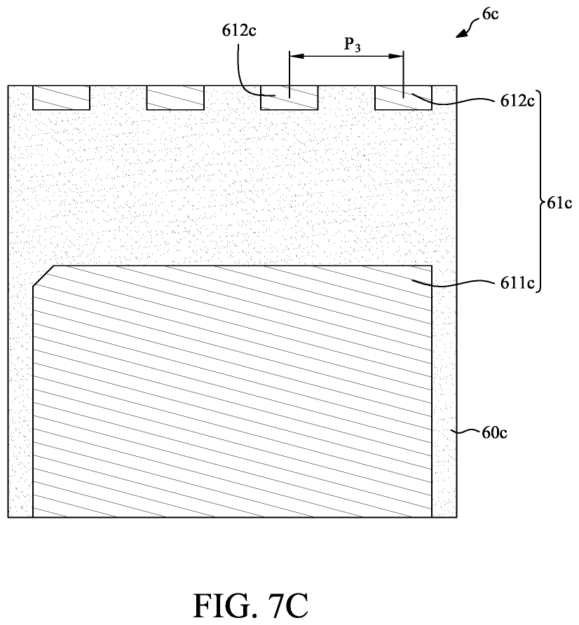

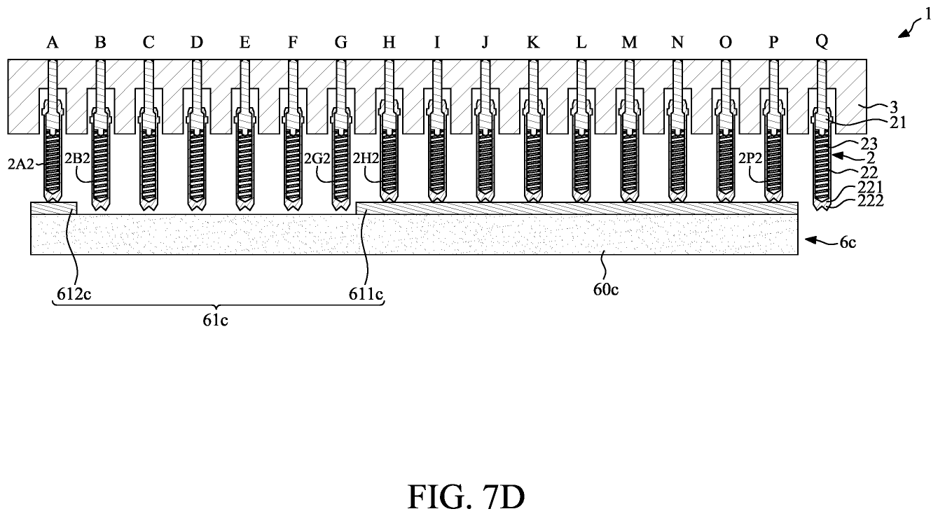

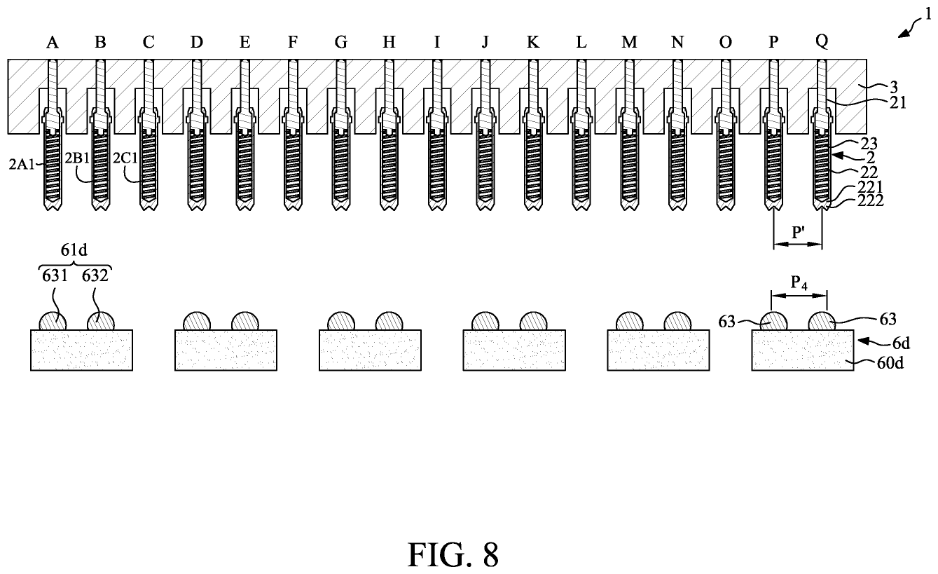

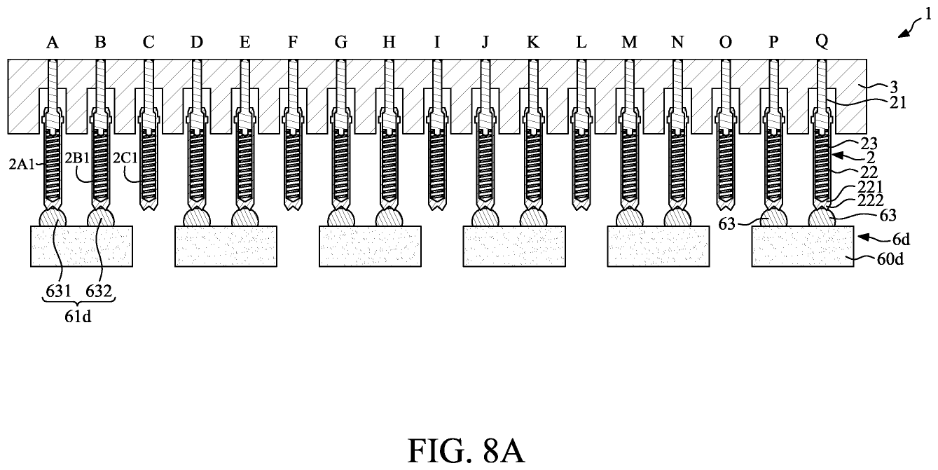

FIG. 1 is an exploded perspective view of a universal probe card 1 according to one embodiment of the disclosure. FIG. 2 is a partially enlarged cross-sectional view of the assembled universal probe card 1 of FIG. 1. FIG. 3 is a schematic diagram showing probes 2 separated from a probe holder 3 of FIG. 2. The universal probe card 1 is configured to test different elements to be tested (for example, an element 6a to be tested of FIG. 5, an element 6a′ to be tested of FIG. 5E, an element 6b to be tested of FIG. 6, an element 6c to be tested of FIG. 7, and an element 6d to be tested of FIG. 8). The elements 6a, 6a′, 6b, 6c, and 6d to be tested may be semiconductor package elements (for example, semiconductor chips), semiconductor dice, semiconductor devices or semiconductor apparatuses. The universal probe card 1 may include a probe holder 3, a circuit board 4, a fixing apparatus 5 and a plurality of probes 2.

The material of the probe holder 3 may be a dielectric material, and the dielectric material may include a glass reinforced epoxy resin material (such as FR4), bismaleimide triazine (BT), epoxy resin, silicon, printed circuit board (PCB) materials, glass, ceramics or photoimageable dielectric (PID) materials. As shown in FIG. 2 and FIG. 3, the probe holder 3 has a first surface 31 (for example, an upper surface) and a second surface 32 (for example, a lower surface). The second surface 32 (for example, the lower surface) is opposite to the first surface 31 (for example, the upper surface). The probe holder 3 defines a plurality of accommodating holes 34 configured to accommodate the probes 2. In one embodiment, the accommodating holes 34 are arranged in an array, and a pitch P″ is formed between the accommodating holes 34. The pitch P″ is a distance between the central axes of the accommodating holes 34. The pitch P″ is substantially uniform, single, or consistent. That is, the distances between the central axes of the accommodating holes 34 are substantially equal to each other.

The pitch P″ of the accommodating holes 34 is a greatest common factor of pitches (for example, a pitch P₁′ of FIG. 5H, a pitch P₂ of FIG. 6C, a pitch P₃ of FIG. 7C, and a pitch P₄ of FIG. 8) between portions to be tested (for example, portions 611a, 612a to be tested of FIG. 5, portions 611a, 612a to be tested of FIG. 5E, portions 611b, 612b to be tested of FIG. 6, portions 611c. 612c to be tested of FIG. 7, and portions 631, 632 to be tested of FIG. 8) in the different patterns to be tested (for example, a pattern 61a to be tested of FIG. 5, a pattern 61a to be tested of FIG. 5E, a pattern 61b to be tested of FIG. 6, a pattern 61c to be tested of FIG. 7, and a pattern 61d to be tested of FIG. 8).

In one embodiment, the accommodating holes 34 may extend through the probe holder 3. That is, the accommodating holes 34 extend to the second surface 32 (for example, the lower surface) from the first surface 31 (for example, the upper surface). Each of the accommodating holes 34 includes a first portion 341 and a second portion 342. The first portion 341 and the second portion 342 communicate with each other, and the width of the first portion 341 may be different from the width of the second portion 342. An opening of the first portion 341 is formed at the first surface 31 (for example, the upper surface) of the probe holder 3. An opening of the second portion 342 is formed at the second surface 32 (for example, the lower surface) of the probe holder 3. In one embodiment, the width of the first portion 341 may be less than the width of the second portion 342. When in a use state, the first portion 211 of the probe 2 is inserted (or plugged) in and fixed to the first portion 341 of the accommodating hole 34, and the first portion 211 of the probe 2 is in close fit to the first portion 341 of the accommodating hole 34. In one embodiment, the probes 2 are withdrawable or detachable. That is, if one of the probes 2 is damaged or needs to be changed, such probe 2 may be unplugged or detached from the accommodating holes 34 of the probe holder 3, and then is replaced with a new probe 2. Alternatively, some accommodating holes 34 do not need the probes 2 inserted (or plugged) thereinto.

The probes 2 are configured to contact and test the patterns to be tested (for example, a pattern 61a to be tested of FIG. 5, a pattern 61b to be tested of FIG. 6, a pattern 61c to be tested of FIG. 7, and a pattern 61d to be tested of FIG. 8) in different elements to be tested. In one embodiment, the patterns to be tested are respectively located on a plurality of separated elements to be tested (for example, an element 6a to be tested of FIG. 5, an element 6b to be tested of FIG. 6, an element 6c to be tested of FIG. 7, and an element 6d to be tested of FIG. 8). In one embodiment, the probe 2 includes a first element 21, a second element 22 and an elastic element 23. It is to be understood that, the structures of the probes 2 in the disclosure are not limited to the structures of the probes 2 shown in FIG. 2 and FIG. 3, and a person skilled in the art can replace the probes 2 shown in FIG. 2 and FIG. 3 with probes having other structures. The second element 22 has a hollow groove, and the hollow groove is substantially of a hollow cylinder structure. The second element 22 has an end portion 221. In one embodiment, the end portion 221 has a plurality of contact tip portions 222. The first element 21 includes a first portion 211 and a second portion 212. The first portion 211 of the first element 21 may be inserted (or plugged) in the first portion 341 of the accommodating hole 34, and the top face of the first portion 211 of the first element 21 is exposed by the first surface 31 (for example, the upper surface) of the probe holder 3. The second portion 212 of the first element 21 may be accommodated in the hollow groove of the second element 22, and may slide relative to the inner side wall of the hollow groove of the second element 22. Therefore, the second portion 212 of the first element 21 is in contact with the inner side wall of the hollow groove of the second element 22, so that the first element 21 is electrically connected to the second element 22. The elastic element 23 (for example, a spring) is accommodated in the hollow groove of the second element 22. One end of the elastic element 23 abuts or sustains against the lower surface of the second portion 212 of the first element 21, and the other end of the elastic element 23 abuts or sustains against the bottom portion or the bottom surface of the hollow groove of the second element 22.

In one embodiment, the first element 21 and the second element 22 are conductive materials. Therefore, the contact tip portions 222 of the second element 22 are electrically connected to the first portion 211 of the first element 21. For example, the first element 21 may include palladium (Pd), copper (Cu), gold (Au), nickel (Ni) or other suitable materials, and the second element 22 may include palladium (Pd), copper (Cu), gold (Au), nickel (Ni) or other suitable materials. The material of the first element 21 and the material of the second element 22 may be the same or different from each other.

In one embodiment, the probes 2 are arranged in an array. A pitch P′ is formed between the probes 2. The pitch P′ is a distance between the central axes of the probes 2. The pitch P′ is substantially uniform, single or consistent. That is, the distances between the central axes of the probes 2 are substantially equal to each other. In one embodiment, the pitch P′ is 500 μm. In one embodiment, the pitch P′ between the probes 2 and the pitch P″ between the accommodating holes 34 are equal to each other. In one embodiment, each pattern to be tested (for example, a pattern 61a to be tested of FIG. 5, a pattern 61a to be tested of FIG. 5E, a pattern 61b to be tested of FIG. 6, a pattern 61c to be tested of FIG. 7, and a pattern 61d to be tested of FIG. 8) includes a plurality of portions to be tested. For example, the pattern 61a to be tested of FIG. 5 includes a plurality of portions 611a, 612a to be tested, the pattern 61a to be tested of FIG. 5E includes a plurality of portions 611a, 612a to be tested, the pattern 61b to be tested of FIG. 6 includes a plurality of portions 611b, 612b to be tested, the pattern 61c to be tested of FIG. 7 includes a plurality of portions 611c. 612c to be tested, and the pattern 61d to be tested of FIG. 8 includes a plurality of portions 631, 632 to be tested. The pitch P′ between the probes 2 is a greatest common factor of the pitches (for example, a pitch P₁′ of FIG. 5H, a pitch P₂ of FIG. 6C, a pitch P₃ of FIG. 7C, and a pitch P₄ of FIG. 8) between the portions to be tested (for example, the portions 611a, 612a to be tested of FIG. 5, the portions 611a, 612a to be tested of FIG. 5E, the portions 611b, 612b to be tested of FIG. 6, the portions 611c, 612c to be tested of FIG. 7, and the portions 631, 632 to be tested of FIG. 8) in the different patterns to be tested (for example, the pattern 61a to be tested of FIG. 5, the pattern 61a to be tested of FIG. 5E, the pattern 61b to be tested of FIG. 6, the pattern 61c to be tested of FIG. 7 and the pattern 61d to be tested of FIG. 8).

In one embodiment, the probes 2 are disposed or distributed in all of the accommodating holes 34. That is, each of the accommodating holes 34 has one probe 2 inserted (or plugged) thereinto. In another embodiment, the probes 2 are not disposed or distributed in all of the accommodating holes 34. That is, some of the accommodating holes 34 may have no probe 2 inserted (or plugged) thereinto. Therefore, at least one group (or at least one part) of the probes 2 are respectively located in at least one group (or at least one part) of the accommodating holes 34.

The circuit board 4 is located on the first surface 31 of the probe holder 3, and is configured to be physically connected to and/or electrically connected to the probes 2 for electrical test. In one embodiment, the circuit board 4 may be a load board, and may include a body 40 and a circuit structure 41. The body 40 may be a printed circuit board, and may include a plurality of electrical pads 42 adjacent to a surface 401 of the body 40. It may be understood that, the body 40 may have circuits (not shown) therein. A pitch P₄₂ is formed between the electrical pads 42. The electrical pads 42 may be electrically connected to an electrical current supply source or a power supply. The circuit board 4 may be electrically connected to a controller or a detector.

The circuit structure 41 may be a redistribution structure, and may have a first surface 411 and a second surface 412. The first surface 411 of the circuit structure 41 is connected to the surface 401 of the body 40. The second surface 412 of the circuit structure 41 is opposite to the first surface 411, and is in contact with the first surface 31 of the probe holder 3. The circuit structure 41 may include a dielectric structure 43, a plurality of inner connection circuits 44 and a plurality of conductive contacts 45. The material of the dielectric structure 43 may include a photosensitive resin or photoimageable dielectric (PID) material, for example, acrylic resin, epoxy resin or polyimide (PI) or other suitable materials. The dielectric structure 43 has a first surface 431 and a second surface 432. The first surface 431 of the dielectric structure 43 is in contact with and covers the surface 401 of the body 40, and covers the electrical pads 42. The first surface 431 of the dielectric structure 43 may be the first surface 411 of the circuit structure 41. In addition, the second surface 432 of the dielectric structure 43 is opposite to the first surface 431, and is in contact with and covers the first surface 31 of the probe holder 3. The second surface 432 of the dielectric structure 43 may be the second surface 412 of the circuit structure 41.

The conductive contacts 45 are adjacent to the second surface 432 (the second surface 412 of the circuit structure 41) of the dielectric structure 43. A pitch P₄₅ is formed between the conductive contacts 45. The end of the first portion 211 of the first element 21 of the probe 2 may be in contact with the conductive contacts 45. Therefore, the pitch P₄₅ between the conductive contacts 45 may be substantially equal to the pitch P′ between the probes 2. Besides, the pitch P₄₅ between the conductive contacts 45 may be substantially equal to the pitch P″ between the accommodating holes 34, so that the conductive contacts 45 may be exposed in the accommodating holes 34. In addition, a pitch P₄₂ between the electrical pads 42 of the body 40 is greater than the pitch P₄₅ between the conductive contacts 45.

The inner connection circuits 44 are electrically connected to the conductive contacts 45 and the electrical pads 42. In one embodiment, each of the inner connection circuits 44 is a conductive path, may include a conductive via and a conductive trace, and is configured to be electrically connected to one conductive contact 45 and one electrical pad 42. That is, the inner connection circuit 44 may be configured to transfer electrical current between the conductive contact 45 and the electrical pad 42. Therefore, when the end of the first portion 211 of the first element 21 of the probe 2 is in contact with the conductive contact 45, the contact tip portion 222 of the second element 22 of the probe 2 is electrically connected to the electrical pad 42.

The fixing apparatus 5 is configured to fix the probe holder 3 and the circuit board 4, so that the probe holder 3 is securely attached to the circuit board 4 to ensure the above-mentioned electrical connection relationship. In one embodiment, the fixing apparatus 5 is a locking apparatus, and may include a bolt (or a screw) and at least one nut. However, it may be understood that, the fixing apparatus 5 may be other fixing apparatuses as long as the fixing apparatus can achieve a function of fixing the probe holder 3 and the circuit board 4. In addition, when the fixing apparatus 5 releases, the probe holder 3 may be separated from the circuit board 4. That is, the probe holder 3 is detachably attached to the circuit board 4.

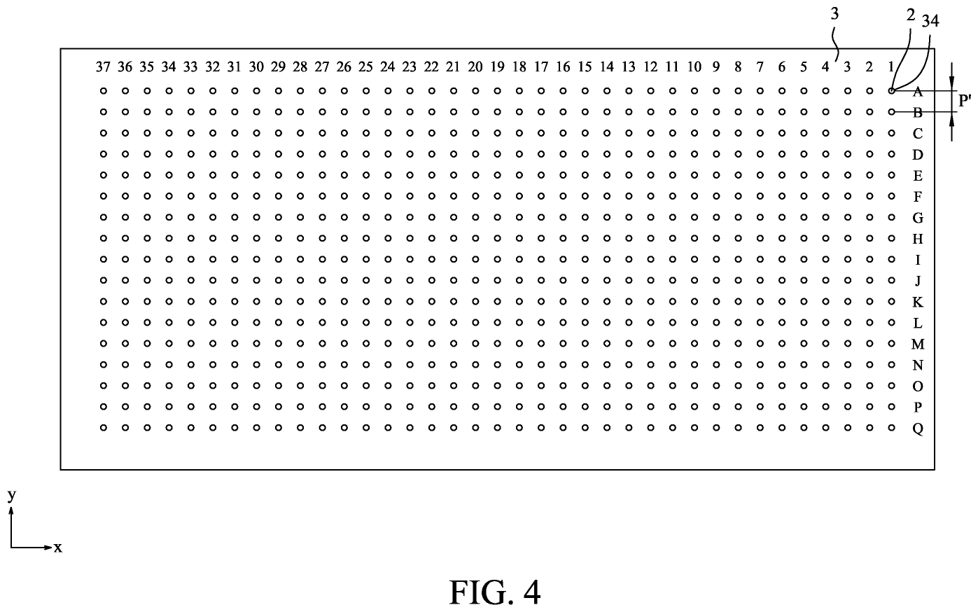

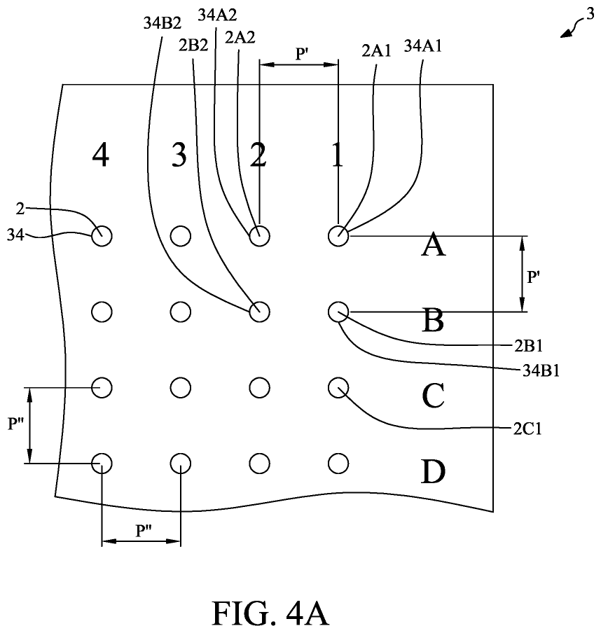

FIG. 4 is a schematic top view showing a combination of the probe holder 3 and the probes 2 of the universal probe card 1 of FIG. 1. FIG. 4A is a partially enlarged view showing the combination of the probe holder 3 and the probes 2 of the universal probe card 1 of FIG. 4. In one embodiment, the probe holder 3 defines the accommodating holes 34. The accommodating holes 34 are arranged in an array, for example, the accommodating holes 34 are arranged in a 17337 matrix including 17 rows (corresponding to reference numerals from A to Q) and 37 columns (corresponding to reference numerals from 1 to 37). For example, FIG. 4A is a partially enlarged view showing the upper right corner of FIG. 4. The accommodating holes 34 include: an accommodating hole 34A1 (corresponding to row A, column 1), an accommodating hole 34B1 (corresponding to row B, column 1), an accommodating hole 34A2 (corresponding to row A, column 2), an accommodating hole 34B2 (corresponding to row B, column 2), and the like. A pitch P″ is formed between the accommodating holes 34, and the pitch P″ is substantially uniform, single or consistent. Besides, the probes 2 are located in the accommodating holes 34, therefore, the probes 2 are also arranged in an array, for example, the probes are arranged in a 17337 matrix including 17 rows (corresponding to reference numerals from A to Q) and 37 columns (corresponding to reference numerals from 1 to 37). For example, the probes 2 include at least: a probe 2A1 (corresponding to row A, column 1, and located in the accommodating hole 34A1), a probe 2B1 (corresponding to row B, column 1, and located in the accommodating hole 34B1), a probe 2C1 (corresponding to row C, column 1), a probe 2A2 (corresponding to row A, column 2, and located in the accommodating hole 34A2), a probe 2B2 (corresponding to row B, column 2, and located in the accommodating hole 34B2), and the like. A pitch P′ is formed between the probes 2, and the pitch P′ is substantially uniform, single or consistent.

FIG. 5 is a perspective view showing the use state of the universal probe card 1 of FIG. 1 to FIG. 4A, wherein the universal probe card 1 is located right above a plurality of elements 6a to be tested, and is not in contact with the elements 6a to be tested. FIG. 5A is a top view of FIG. 5. FIG. 5B is a cross-sectional view along line I-I of FIG. 5A. FIG. 5C is a top view of a single element 6a to be tested. It should be noted that, for the sake of clarity of illustration, the circuit board 4 is omitted from the universal probe card 1 of FIG. 5, FIG. 5A and FIG. 5B, and only the combination of the probe holder 3 and the probes 2 is shown.

Referring to FIG. 5C, in one embodiment, the element 6a to be tested may be a semiconductor element, a semiconductor device, or a semiconductor package element, for example, suitable package structures including a quad flat no-lead (QFN) package, a dual flat no-lead (DFN) package, a small outline no-lead (SON) package, a small outline diode (SOD), a ball grid array (BGA) package, a land grid array (LGA) package and the like. The element 6a to be tested may include a body 60a and at least one pattern 61a to be tested. The body 60a may include at least one electrical element (for example, at least one semiconductor die or at least one semiconductor chip) and a molding compound for encapsulating the electrical element (for example, the semiconductor die or the semiconductor chip). The pattern 61a to be tested is exposed by one surface (upper surface) of the body 60a for external electrical connection, or for electrical test. The pattern 61a to be tested includes one or more portions 611a, 612a to be tested. Referring to FIG. 5 and FIG. 5B, the portions 611a, 612a to be tested are bonding pads or electrical contacts, protrude from one surface of the body 60a, and are spaced apart from one another or separated from one another. A pitch P1 is formed between the portions 611a, 612a to be tested, and the pitch P₁ is substantially uniform, single or consistent. The pitch P₁ is defined as follows: the portion 611a to be tested has a first side 6111, a second side 6112 and a central point 611ac. The first side 6111 is along the x-direction of the figure, the second side 6112 is along the y-direction of the figure, and the center of the first side 6111 and the center of the second side 6112 collectively define the central point 611ac. That is, the central point 611ac is the intersection point of the imaginary extension line of the center of the first side 6111 along the y-direction and the imaginary extension line of the center of the second side 6112 along the x-direction. The central point 611ac may be the geometric center of the portion 611a to be tested, or may not be the geometric center of the portion 611a to be tested. Besides, the portion 612a to be tested has a first side 6121, a second side 6122 and a central point 612ac, the first side 6121 is along the x-direction of the figure, the second side 6122 is along the y-direction of the figure, and the center of the first side 6121 and the center of the second side 6122 collectively define the central point 612ac. That is, the central point 612ac is the intersection point of the imaginary extension line of the center of the first side 6121 along the y-direction and the imaginary extension line of the center of the second side 6122 along the x-direction. The central point 612ac may be the geometric center of the portion 612a to be tested, or may not be the geometric center of the portion 612a to be tested. The pitch P₁ is a distance between the central point 611ac and the central point 612ac along the y-direction. In one embodiment, the pitch P₁ is 500 μm or 580 μm.

In one embodiment, the pitch P₁ between the portions 611a, 612a to be tested may be equal to or may not be equal to the pitch P′ between the probes 2. In one embodiment, the pitch P₁ between the portions 611a, 612a to be tested may be slightly greater than the pitch P′ between the probes 2, as long as a gap or spacing D (FIG. 5C) between the portions 611a, 612a to be tested is less than the pitch P′ between the probes 2. In addition, the width W (FIG. 5C) of the element 6a to be tested may be equal to, less than or greater than the pitch P′ between the probes 2. In one embodiment, the width W (FIG. 5C) of the element 6a to be tested is less than twice the pitch P′ between the probes 2.

Referring to FIG. 5, FIG. 5A and FIG. 5B, when in the use state, the elements 6a to be tested are arranged into a predetermined array firstly. That is, the elements 6a to be tested are a plurality of semiconductor elements separated from one another. In the x-direction of FIG. 5A, a pitch P₁′ is formed between the portions 611a, 612a to be tested of two adjacent elements 6a to be tested. For example, the distance in the x-direction between the geometric centers of the portions 612a to be tested of two adjacent elements 6a to be tested is the pitch P₁′. The pitch P₁′ is twice the pitch P′ between the probes 2. In one embodiment, the pitch P₁′ is 1000 μm. Then, the universal probe card 1 moves to a position over the elements 6a to be tested, and is not in contact with the elements 6a to be tested. Therefore, in FIG. 5A and FIG. 5B, the probe 2A1 corresponds to the portion 612a to be tested. That is, the probe 2A1 is located right above the portion 612a to be tested. The probe 2B1 corresponds to the portion 611a to be tested. That is, the probe 2B1 is located right above the portion 611a to be tested. Meanwhile, the probe 2C1 does not correspond to any portion to be tested. That is, there is no portion to be tested right below the probe 2C1.

FIG. 5D is a cross-sectional view showing the use state of the universal probe card 1 of FIG. 5B. In this case, the universal probe card 1 (including the combination of the probe holder 3 and the probes 2) and the elements 6a to be tested relatively move in the vertical direction (i.e., z-direction), and are in contact with each other. For example, the element 6a to be tested is fixed, the universal probe card 1 (including the combination of the probe holder 3 and the probes 2) moves downward, so that the probes 2 are in contact with the pattern 61a to be tested (including the portions 611a, 612a to be tested) of the elements 6a to be tested. Alternatively, the universal probe card 1 (including the combination of the probe holder 3 and the probes 2) is fixed, and the elements 6a to be tested move upward, so that the probes 2 are in contact with the pattern 61a to be tested (including the portions 611a, 612a to be tested) of the elements 6a to be tested.

As shown in FIG. 5D, the probe 2A1 is in contact with the portion 612a to be tested, the probe 2B1 is in contact with the portion 611a to be tested, and the probe 2C1 is not in contact with any portion to be tested. Meanwhile, the portion 612a to be tested is electrically connected to the circuit board 4 (FIG. 1 and FIG. 2) through the probe 2A1, and the portion 611a to be tested is electrically connected to the circuit board 4 through the probe 2B1. Then, by transmitting a test signal or a test electrical current to the portions 611a, 612a to be tested of each of the elements 6a to be tested through the circuit board 4, electrical tests are performed on all of the elements 6a to be tested at the same time. For example, the quality or functions of all of the elements 6a to be tested may be tested at the same time, thereby implementing multi-site probing. The units per hour of the testing method of the universal probe card 1 is fairly high, and the tested elements 6a have traceability.

In one embodiment, the probe 2C1 may be omitted. That is, not all of the accommodating holes 34 may be inserted with the probes 2. Some accommodating holes 34 are empty and have no probe inserted thereinto. Therefore, the arrangement mode or arrangement manner of the probes 2 may be determined according to the arrangement mode or arrangement manner of the pattern 61a to be tested of the elements 6a to be tested and the arrangement mode or arrangement manner of the elements 6a to be tested.

FIG. 5E is a perspective view showing the use state of the universal probe card 1 of FIG. 1 to FIG. 4A, wherein the universal probe card 1 is located right above an apparatus 6′ to be tested (including a plurality of elements 6a′ to be tested), and is not in contact with the apparatus 6′ to be tested. FIG. 5F is a top view of FIG. 5E. FIG. 5G is a cross-sectional view along line I′-I′ of FIG. 5F. FIG. 5H is a partially enlarged view of the apparatus 6′ to be tested of FIG. 5E. It should be noted that, for the sake of clarity of illustration, the circuit board 4 is omitted from the universal probe card 1 of FIG. 5E, FIG. 5F and FIG. 5G, and only the combination of the probe holder 3 and the probes 2 is shown.

Referring to FIG. 5E and FIG. 5H, in one embodiment, the apparatus 6′ to be tested may be an element to be tested. The apparatus 6′ to be tested may be in the shape of a panel or a wafer, and may be a semiconductor device or a semiconductor package element. The apparatus 6′ to be tested may include a plurality of elements 6a′ to be tested (or referred to as units to be tested). That is, the elements 6a′ to be tested (or the units to be tested) are connected together, and each of the elements 6a′ to be tested is a part of the apparatus 6′ to be tested. The patterns 61a to be tested are located on the same apparatus 6′ to be tested. In one embodiment, the apparatus 6′ to be tested may be singualted to form a plurality of elements 6a to be tested as shown in FIG. 5 to FIG. 5D. That is, the elements 6a′ to be tested of FIG. 5H may be same as or similar to the elements 6a to be tested of FIG. 5 to FIG. 5D.

The apparatus 6′ to be tested may include a body 60a′ and a plurality of patterns 61a to be tested. The body 60a′ may include a plurality of electrical elements (for example, semiconductor dice or semiconductor chips) and a molding compound encapsulating the electrical elements (for example, the semiconductor dice or the semiconductor chips). The patterns 61a to be tested are located on the same semiconductor element (namely the apparatus 6′ to be tested). The patterns 61a to be tested are exposed by one surface (upper surface) of the body 60a′ for external electrical connection, or for electrical test. The pattern 61a to be tested includes one or more portions 611a, 612a to be tested.

In the x-direction of FIG. 5H, a pitch P₁′ is formed between the portions 611a, 612a to be tested of two adjacent elements 6a′ to be tested. For example, the distance in the x-direction between the geometric centers of the portions 612a to be tested of two adjacent elements 6a′ to be tested is the pitch P₁′. The pitch P₁′ is twice the pitch P′ between the probes 2. In FIG. 5E, FIG. 5F and FIG. 5G, the universal probe card 1 is located right above the apparatus 6′ to be tested, and is not in contact with the elements 6a to be tested of the apparatus 6′ to be tested. Therefore, in FIG. 5F and FIG. 5G, the probe 2A1 corresponds to the portion 612a to be tested, and the probe 2B1 corresponds to the portion 611a to be tested. In this case, the probe 2C1 does not correspond to any portion to be tested.

Then, the universal probe card 1 (including the combination of the probe holder 3 and the probes 2) and the apparatus 6′ to be tested relatively move in the vertical direction, and are in contact with each other, so that the probe 2A1 is in contact with the portion 612a to be tested, and the probe 2B1 is in contact with the portion 611a to be tested for performing a testing process, thereby implementing full wafer probing.

FIG. 6 is a perspective view showing the use state of the universal probe card 1 according to one embodiment of the disclosure, wherein the universal probe card 1 is located right above a plurality of elements 6b to be tested, and is not in contact with the elements 6b to be tested. FIG. 6A is a top view of FIG. 6. FIG. 6B is a cross-sectional view along line II-II of FIG. 6A. FIG. 6C is a top view of the single element 6b to be tested. It should be noted that, for the sake of clarity of illustration, the circuit board 4 is omitted from the universal probe card 1 of FIG. 6, FIG. 6A and FIG. 6B, and only the combination of the probe holder 3 and the probes 2 is shown.

Referring to FIG. 6C, in one embodiment, the element 6b to be tested may be a semiconductor element, a semiconductor device, or a semiconductor package element, and is similar to the element 6a to be tested of FIG. 5C. The element 6b to be tested may include a body 60b and at least one pattern 61b to be tested. The body 60b may include at least one electrical element and a molding compound encapsulating the electrical element. The pattern 61b to be tested is exposed by one surface (upper surface) of the body 60b for external electrical connection, or for electrical test. The pattern 61b to be tested includes a portion 611b to be tested and a plurality of portions 612b to be tested. Referring to FIG. 6 and FIG. 6B, the portions 611b, 612b to be tested are bonding pads or electrical contacts, protrude from one surface of the body 60b, and are spaced from each other or separated from each other. A pitch P₂ is formed between the portions 612b to be tested, and the pitch P₂ is substantially uniform, single or consistent. The pitch P₂ is defined as the distance between the geometric centers of the portions 612b to be tested. In one embodiment, the pitch P₂ is 1500 μm. It should be noted that, since the size (or area) of the portion 611b to be tested is much greater than the size (or area) of the portion 612b to be tested, the pitch between the portion 611b to be tested and the portion 612b to be tested may be not taken into consideration. That is, the pitch P₂ is determined by the pitch between the portions 612b to be tested with the minimum size (or area) in the pattern 61b to be tested.

Referring to FIG. 6, FIG. 6A and FIG. 6B, when in the use state, the elements 6b to be tested are arranged into a predetermined array firstly. Then, the universal probe card 1 moves to a position right above the elements 6b to be tested, and is not in contact with the elements 6b to be tested. Meanwhile, the probe 2A2 and the probe 2B2 correspond to the portion 612b to be tested. That is, the probe 2A2 and the probe 2B2 are located right above the portion 612b to be tested. Besides, the probe 2E2 to the probe 2M2 correspond to the portion 611b to be tested. That is, the probes from the probe 2E2 to the probe 2M2 are located right above the portion 611b to be tested. In this case, the probe 2C2 and the probe 2D2 do not correspond to any portions to be tested. That is, there is no portion to be tested below the probe 2C2 and the probe 2D2.

FIG. 6D is a cross-sectional view showing the use state of the universal probe card 1 of FIG. 6B. In this case, the universal probe card 1 (including the combination of the probe holder 3 and the probes 2) is in contact with the elements 6b to be tested. For example, the probe 2A2 and the probe 2B2 are in contact with the portion 612b to be tested, the probes from the probe 2E2 to the probe 2M2 are in contact with the portion 611b to be tested, and the probe 2C2 and the probe 2D2 are not in contact with any portions to be tested. Meanwhile, the portion 612b to be tested is electrically connected to the circuit board 4 through the probe 2A2 and the probe 2B2, and the portion 611b to be tested is electrically connected to the circuit board 4 through the probes from the probe 2E2 to the probe 2M2. Then, by transmitting a test signal or a test electrical current to the portions 611b, 612b to be tested of each of the elements 6b to be tested through the circuit board 4, electrical tests are performed on all of the elements 6b to be tested at the same time. For example, the quality or functions of each of the elements 6b to be tested may be tested at the same time.

In one embodiment, the probe 2C2 and the probe 2D2 may be omitted. That is, not all of the accommodating holes 34 may be inserted with the probes 2, and some accommodating holes 34 are empty and have no probe inserted thereinto. Besides, some of the probes from the probe 2E2 to the probe 2M2 may also be omitted. Therefore, the arrangement mode or arrangement manner of the probes 2 may be determined by the arrangement mode or arrangement manner of the patterns 61b to be tested of the elements 6b to be tested and the arrangement mode or arrangement manner of the elements 6b to be tested.

In one embodiment, the elements 6b to be tested may be located on a same apparatus to be tested, and the apparatus to be tested may also be an element to be tested. Such apparatus to be tested may be in the shape of a panel or a wafer, and may be a semiconductor element or a semiconductor package element. The apparatus to be tested may include the elements 6b to be tested (or referred to as the units to be tested). That is, the elements 6b to be tested (or the units to be tested) are connected together, and each of the elements 6b to be tested is a part of the apparatus to be tested.

FIG. 7 is a perspective view showing the use state of the universal probe card 1 according to one embodiment of the disclosure, wherein the universal probe card 1 is located right above a plurality of elements 6c to be tested, and is not in contact with the elements 6c to be tested. FIG. 7A is a top view of FIG. 7. FIG. 7B is a cross-sectional view along line III-III of FIG. 7A. FIG. 7C is a top view of the single element 6c to be tested. It should be noted that, for the sake of clarity of illustration, the circuit board 4 is omitted from the universal probe card 1 of FIG. 7, FIG. 7A and FIG. 7B, and only the combination of the probe holder 3 and the probes 2 is shown.

Referring to FIG. 7C, in one embodiment, the element 6c to be tested may be a semiconductor element, a semiconductor device, or a semiconductor package element, and is similar to the element 6a to be tested of FIG. 5C and the element 6b to be tested of FIG. 6C. The element 6c to be tested may include a body 60c and at least one pattern 61c to be tested. The body 60c may include at least one electrical element and a molding compound encapsulating the electrical element. The pattern 61c to be tested is exposed by one surface (upper surface) of the body 60c for external electrical connection, or for electrical test. The pattern 61c to be tested includes a portion 611c to be tested and a plurality of portions 612c to be tested. Referring to FIG. 7 and FIG. 7B, the portions 611c, 612c to be tested are bonding pads or electrical contacts, protrude from one surface of the body 60c, and are spaced from each other or separated from each other. A pitch P₃ is formed between the portions 612c to be tested, and the pitch P₃ is substantially uniform, single or consistent. The pitch P₃ is defined as the distance between the geometric centers of the portions 612c to be tested. In one embodiment, the pitch P₃ is 2000 μm. It should be noted that, since the size (or area) of the portion 611c to be tested is much greater than the size (or area) of the portion 612c to be tested, the pitch between the portion 611c to be tested and the portion 612c to be tested may be not taken into consideration. That is, the pitch P₃ is determined by the pitch between the portions 612c to be tested with the minimum size (or area) in the pattern 61c to be tested.

Referring to FIG. 7, FIG. 7A and FIG. 7B, when in the use state, the elements 6c to be tested are arranged into a predetermined array firstly. Then, the universal probe card 1 moves to a position over the elements 6c to be tested, and is not in contact with the elements 6c to be tested. Meanwhile, the probe 2A2 corresponds to the portion 612c to be tested. That is, the probe 2A2 is located right above the portion 612c to be tested. Besides, the probe 2H2 to the probe 2P2 correspond to the portion 611c to be tested, that is, the probes from the probe 2H2 to the probe 2P2 are located right above the portion 611c to be tested. In this case, the probe 2B2 to the probe 2G2 do not correspond to any portions to be tested. That is, there is no portion to be tested below the probe 2B2 to the probe 2G2.

FIG. 7D is a cross-sectional view showing the use state of the universal probe card 1 of FIG. 7B. In this case, the universal probe card 1 (including the combination of the probe holder 3 and the probes 2) is in contact with the elements 6c to be tested. For example, the probe 2A2 is in contact with the portion 612c to be tested, the probes from the probe 2H2 to the probe 2P2 is in contact with the portion 611c to be tested, and the probe 2B2 to the probe 2G2 are not in contact with any portions to be tested. Meanwhile, the portion 612c to be tested is electrically connected to the circuit board 4 through the probe 2A2, and the portion 611c to be tested is electrically connected to the circuit board 4 through the probes from the probe 2H2 to the probe 2P2. Then, by transmitting a test signal or a test electrical current to the portions 611c, 612c to be tested of each of the elements 6c to be tested through the circuit board 4, electrical tests are performed on all of the elements 6c to be tested at the same time.

In one embodiment, all or part of the probes between the probe 2B2 and the probe 2G2 may be omitted. That is, not all of the accommodating holes 34 may be inserted with the probes 2, and some accommodating holes 34 are empty and have no probe inserted thereinto. Besides, part of the probes from the probe 2H2 to the probe 2G2 may also be omitted. Therefore, the arrangement mode or arrangement manner of the probes 2 may be determined by the arrangement mode or arrangement manner of the patterns 61c to be tested of the elements 6c to be tested and the arrangement mode or arrangement manner of the elements 6c to be tested.

FIG. 8 is a cross-sectional view showing the use state of the universal probe card 1 according to one embodiment of the disclosure, wherein the universal probe card 1 is located right above a plurality of elements 6d to be tested, and is not in contact with the elements 6d to be tested. In one embodiment, the element 6d to be tested may be a semiconductor element, a semiconductor device, or a semiconductor package element, and may include a body 60d and at least one pattern 61d to be tested. The body 60d may include at least one electrical element and a molding compound encapsulating the electrical element. The pattern 61d to be tested is exposed by one surface (upper surface) of the body 60d for external electrical connection, or for electrical test. The pattern 61d to be tested includes a plurality of portions 63 to be tested (including, for example, portions 631, 632 to be tested). The portions 63 to be tested are bumps or solder balls, protrude from a surface of the body 60d, and are spaced from each other or separated from each other. A pitch P₄ is formed between the portions 63 to be tested, and the pitch P₄ is substantially uniform, single or consistent. The pitch P₄ is defined as a distance between the geometric centers of the portions 63 to be tested. In one embodiment, the pitch P₄ is 500 μm or 600 μm.

When in the use state, the elements 6d to be tested are arranged into a predetermined array firstly. Then, the universal probe card 1 (including the combination of the probe holder 3 and the probes 2) moves to a position over the elements 6d to be tested, and is not in contact with the elements 6d to be tested. In this case, the probe 2A1 corresponds to the portion 631 to be tested. That is, the probe 2A1 is located right above the portion 631 to be tested. Besides, the probe 2B1 corresponds to the portion 632 to be tested. That is, the probe 2B1 is located right above the portion 632 to be tested. In this case, the probe 2C1 does not correspond to any portion to be tested. That is, there is no portion to be tested below the probe 2C1.

FIG. 8A is a cross-sectional view showing the use state of the universal probe card 1 of FIG. 8, wherein the universal probe card 1 is in contact with the elements 6d to be tested. For example, the probe 2A1 is in contact with the portion 631 to be tested, the probe 2B1 is in contact with the portion 632 to be tested, and the probe 2C1 is not in contact with any portion to be tested. Then, by transmitting a test signal or a test electrical current to the portions 63 to be tested (for example, the portions 631, 632 to be tested) of each of the elements 6d to be tested through the circuit board 4, electrical tests are performed on all of the elements 6d to be tested at the same time.

In FIG. 5 to FIG. 8A, the pitch P′ between the probes 2 is a greatest common factor of the pitches (for example, the pitch P₁′ of FIG. 5H, the pitch P₂ of FIG. 6C, the pitch P₃ of FIG. 7C, and the pitch P₄ of FIG. 8) of the portions to be tested (for example, the portions 611a, 612a to be tested of FIG. 5, the portions 611a, 612a to be tested of FIG. 5E, the portions 611b, 612b to be tested of FIG. 6, the portions 611c, 612c to be tested of FIG. 7, and the portions 631, 632 to be tested of FIG. 8) of the different patterns to be tested (for example, the pattern 61a to be tested of FIG. 5, the pattern 61a to be tested of FIG. 5E, the pattern 61b to be tested of FIG. 6, the pattern 61c to be tested of FIG. 7, and the pattern 61d to be tested of FIG. 8), and therefore, the universal probe card 1 is suitable for testing different elements to be tested (for example, the element 6a to be tested of FIG. 5, the element 6a′ to be tested of FIG. 5E, the elements 6b to be tested of FIG. 6, the elements 6c to be tested of FIG. 7, and the elements 6d to be tested of FIG. 8), and is universal. That is, the probe holder 3 is a universal or general probe holder.

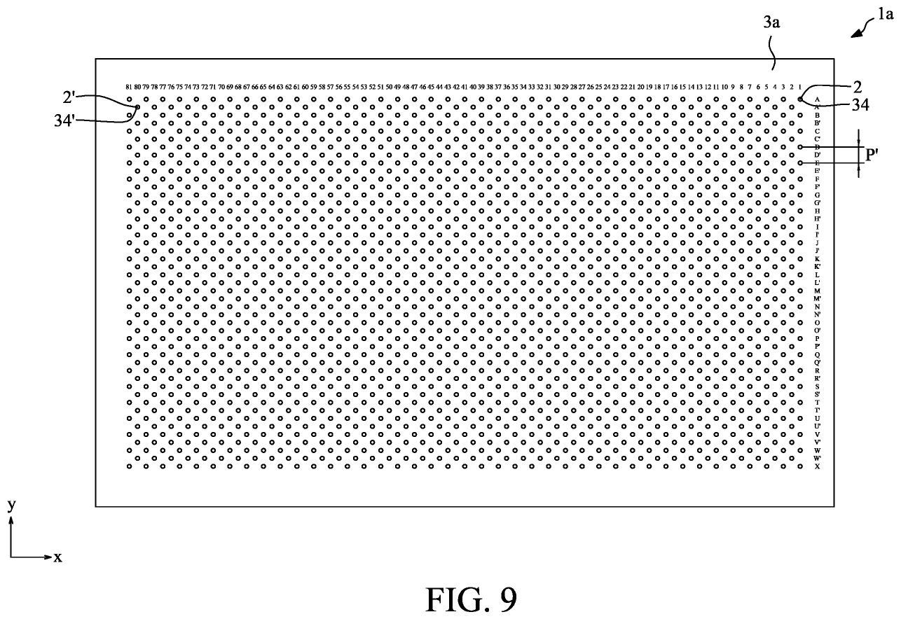

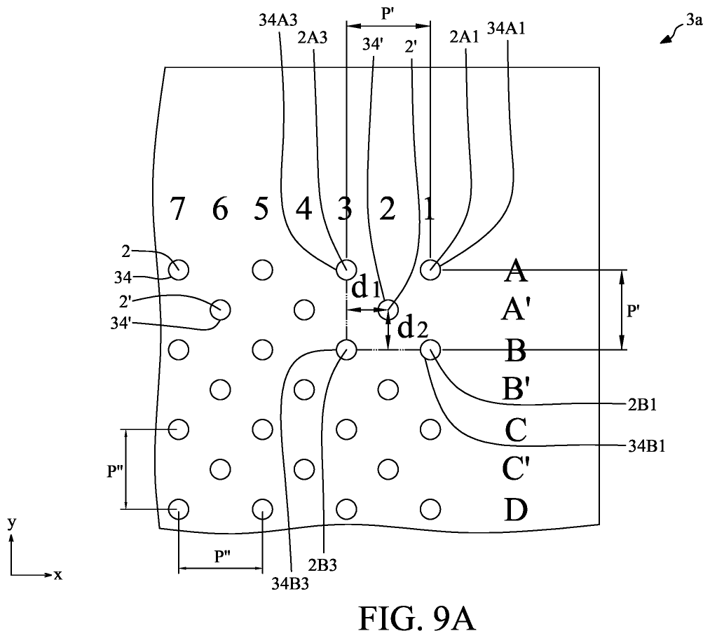

FIG. 9 is a schematic top view of a combination of a probe holder 3a and a plurality of probes 2, 2′ of a universal probe card 1a according to one embodiment of the disclosure. FIG. 9A is a partially enlarged view showing the combination of the probe holder 3a and the probes 2, 2′ of the universal probe card 1a of FIG. 9. It should be noted that, for the sake of clarity of illustration, the circuit board 4 is omitted from the universal probe card 1a of FIG. 9 and FIG. 9A, and only the combination of the probe holder 3a and the probes 2, 2′ is shown. The universal probe card 1a (including the probe holder 3a and the probes 2, 2′) of FIG. 9 and FIG. 9A is substantially same as or similar to the universal probe card 1 (including the probe holder 3 and the probes 2) of FIG. 1 to FIG. 4A, except for the arrangement mode or arrangement manner of accommodating holes 34, 34′ of the probe holder 3a and the arrangement mode or arrangement manner of the probes 2, 2′. As shown in FIG. 9 and FIG. 9A, the accommodating holes 34, 34′ of the probe holder 3a and the probes 2, 2′ are arranged in a staggered manner.

In one embodiment, the probe holder 3a defines a plurality of first accommodating holes 34 and a plurality of second accommodating holes 34′. The first accommodating holes 34 are the same as the accommodating holes 34 of FIG. 4 and FIG. 4A, and are arranged in an array including 24 rows (corresponding to reference numerals from A, B, C to X, except for A′, B′, C′ and the like) and 41 columns (corresponding to reference numerals being odd numbers from 1 to 81). For example, the first accommodating holes 34 include: an accommodating hole 34A1 (corresponding to row A, column 1), an accommodating hole 34B1 (corresponding to row B, column 1), an accommodating hole 34A3 (corresponding to row A, column 3), an accommodating hole 34B3 (corresponding to row B, column 3), and the like. For example, the accommodating hole 34A3 (corresponding to row A, column 3) and the accommodating hole 34B3 (corresponding to row B column 3) of the figure are respectively the same as the accommodating hole 34A2 (corresponding to row A, column 2) and the accommodating hole 34B2 (corresponding to row B, column 2) of FIG. 4A. A pitch P″ is formed between the first accommodating holes 34, and the pitch P″ is substantially uniform, single or consistent. The pitch P″ of FIG. 9A is equal to the pitch P″ between the accommodating holes 34 of FIG. 4 and FIG. 4A.

The second accommodating holes 34′ are also arranged in an array including 23 rows (corresponding to reference numerals from A′, B′, C′ to W′, except for A, B, C and the like) and 40 columns (corresponding to reference numerals being even numbers from 1 to 81). The array of the second accommodating holes 34′ and the array of the first accommodating holes 34 are staggered from each other. That is, a row of the second accommodating holes 34′ is located between two adjacent rows of the first accommodating holes 34. For example, the row A′ of the second accommodating holes 34′ is located between the row A of the first accommodating holes 34 and the row B of the first accommodating holes 34. An offset is formed between the rows of the second accommodating holes 34′ and the rows of the first accommodating holes 34. That is, the second accommodating holes 34′ are not aligned with the first accommodating holes 34. In addition, a column of the second accommodating holes 34′ is located between two adjacent columns of the first accommodating holes 34. For example, the column 2 of the second accommodating holes 34′ is located between the column 1 of the first accommodating holes 34 and the column 3 of the first accommodating holes 34. An offset is formed between the columns of the second accommodating holes 34′ and the columns of the first accommodating holes 34.

A pitch is formed between the second accommodating holes 34′, and the value of such pitch is equal to the value of the pitch P″ between the first accommodating holes 34. In one embodiment, one second accommodating hole 34′ is located at the central point of four first accommodating holes 34 closest to such second accommodating hole 34′. Therefore, the shortest distance d₁ between the projection of the center of the second accommodating hole 34′ and the projection of the center of the first accommodating hole 34 along the y-direction in the figure is one half of the pitch P″, and the shortest distance d₂ between the projection of the center of the second accommodating hole 34′ and the projection of the center of the first accommodating hole 34 along the x-direction in the figure is one half of the pitch P″. The distance d₁ is equal to the distance d₂.

The probes 2, 2′ include a plurality of first probes 2 and a plurality of second probes 2′. The first probes 2 and the second probes 2′ are respectively located in the first accommodating holes 34 and the second accommodating holes 34′. The first probes 2 are the same as the probes 2 of FIG. 4 and FIG. 4A, and are arranged in an array including 24 rows (corresponding to reference numerals from A, B, C to X, except for A′, B′. C′ and the like) and 41 columns (corresponding to reference numerals being odd numbers from 1 to 81). For example, the first probes 2 include at least: a probe 2A1 (corresponding to row A, column 1, and located in the accommodating hole 34A1), a probe 2B1 (corresponding to row B, column 1, and located in the accommodating hole 34B1), a probe 2A3 (corresponding to row A, column 3, located in the accommodating hole 34A3), a probe 2B3 (corresponding to row B, column 3, and located in the accommodating hole 34B3), and the like. A pitch P′ is formed between the first probes 2, and the pitch P′ is substantially uniform, single or consistent, and is equal to the pitch P′ between the probes 2 of FIG. 4 and FIG. 4A. For example, the probe 2A3 (corresponding to row A, column 3) and the probe 2B3 (corresponding to row B, column 3) of the figure are respectively the same as the probe 2A2 (corresponding to row A, column 2) and the probe 2B2 (corresponding to row B, column 2) of FIG. 4A.

The second probes 2′ are also arranged in an array including 23 rows (corresponding to reference numerals from A′, B′, C′ to W′, except for A, B, C and the like) and 40 columns (corresponding to reference numerals being even number from 1 to 81). The array of the second probes 2′ and the array of the first probes 2 are staggered from each other. That is, a row of the second probes 2′ is located between two adjacent rows of the first probes 2. For example, the row A′ of the second probes 2′ is located between the row A of the first probes 2 and the row B of the first probes 2. An offset is formed between the row of the second probes 2′ and the row of the first probes 2. That is, the row of the second probes 2′ is not aligned with the row of the first probes 2. In addition, a column of the second probes 2′ is located between two adjacent columns of the first probes 2. For example, the column 2 of the second probes 2′ is located between the column 1 of the first probes 2 and the column 3 of the first probes. An offset is formed between the column of the second probes 2′ and the column of the first probes 2.

A pitch is formed between the second probes 2′, and the value of such pitch is equal to the value of the pitch P′ between the first probes 2. In one embodiment, one second probe 2′ is located at a central point of four first probes 2 closest to such second probe 2′. Therefore, the shortest distance d₁ between the projection of the center of the second probe 2′ and the projection of the center of the first probe 2 along the y-direction in the figure is one half of the pitch P′. The shortest distance d₂ between the projection of the center of the second probe 2′ and the projection of the center of the first probe 2 along the x-direction in the figure is one half of the pitch P′. The distance d₁ is equal to the distance d₂.

Compared with FIG. 4 and FIG. 4A, the accommodating holes 34, 34′ of the probe holder 3a and the probes 2, 2′ shown in FIG. 9 and FIG. 9A are arranged more closely, so that more types of elements to be tested can be tested, and the patterns to be tested of the applicable elements to be tested are more various and flexible.

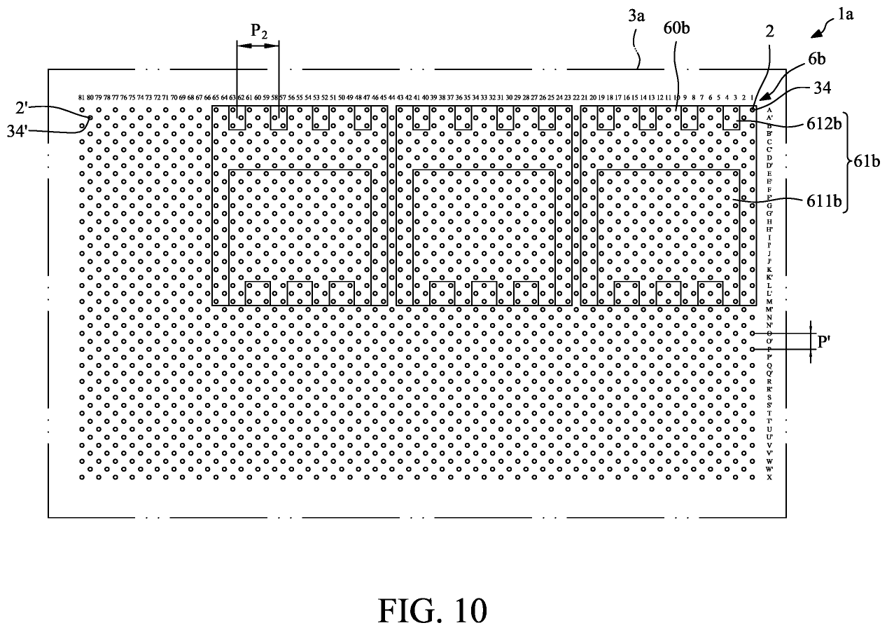

FIG. 10 is a schematic top view showing the use state of the universal probe card 1a of FIG. 9, wherein the universal probe card 1a is located right above the plurality of elements 6b to be tested. It should be noted that, for the sake of clarity of illustration, the circuit board 4 is omitted from the universal probe card 1a of FIG. 10, and only the combination of the probe holder 3a and the probes 2, 2′ is shown. The structure shown in FIG. 10 is substantially similar to the structure shown in FIG. 6A, wherein the elements 6b to be tested of the two are the same. The difference between the structure shown in FIG. 10 and the structure shown in FIG. 6A is that the universal probe card 1a (including the combination of the probe holder 3a and the probes 2, 2′) of FIG. 10 is the universal probe card 1a (including the combination of the probe holder 3a and the probes 2, 2′) of FIG. 9.

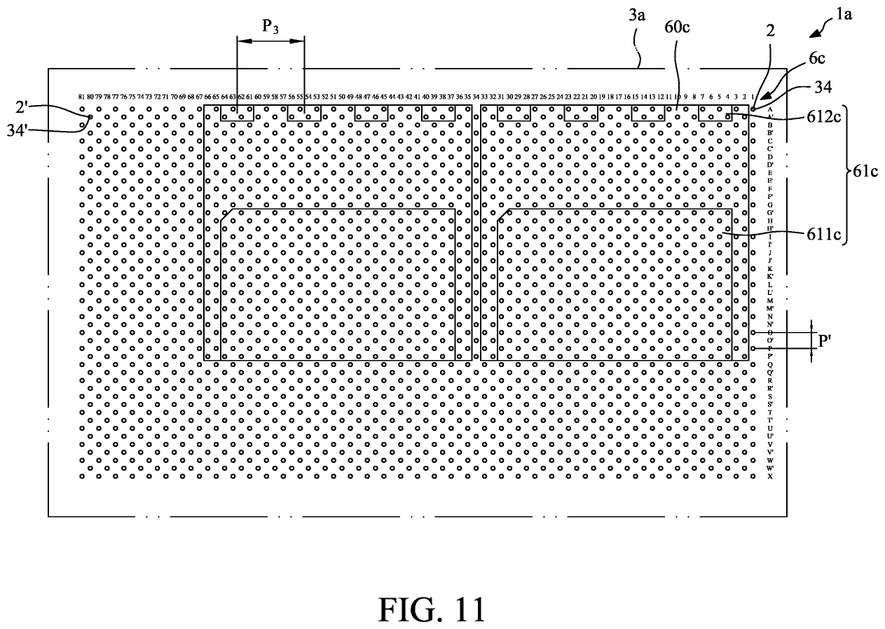

FIG. 11 is a schematic top view showing the use state of the universal probe card 1a of FIG. 9, wherein the universal probe card 1a is located right above the plurality of elements 6c to be tested. It should be noted that, for the sake of clarity of illustration, the circuit board 4 is omitted from the universal probe card 1a of FIG. 11, and only the combination of the probe holder 3a and the probes 2, 2′ is shown. The structure shown in FIG. 11 is substantially similar to the structure shown in FIG. 7A, wherein the elements 6c to be tested of the two are the same. The difference between the structure shown in FIG. 11 and the structure shown in FIG. 7A is that the universal probe card 1a (including the combination of the probe holder 3a and the probes 2, 2′) of FIG. 11 is the universal probe card 1a (including the combination of the probe holder 3a and the probes 2, 2′) of FIG. 9.

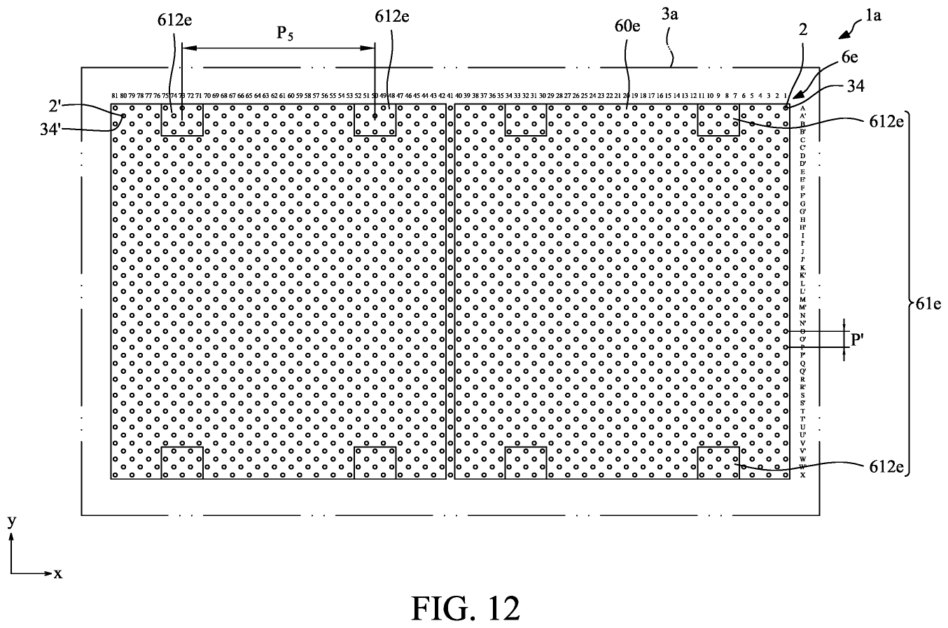

FIG. 12 is a schematic top view showing the use state of the universal probe card 1a of FIG. 9, wherein the universal probe card 1a is located right above the plurality of elements 6e to be tested. It should be noted that, for the sake of clarity of illustration, the circuit board 4 is omitted from the universal probe card 1a of FIG. 12, and only the combination of the probe holder 3a and the probes 2, 2′ is shown. An element 6e to be tested of FIG. 12 may include a body 60e and at least one pattern 61e to be tested. The body 60e may include at least one electrical element and a molding compound encapsulating the electrical element. The pattern 61e to be tested is exposed by one surface (upper surface) of the body 60e for external electrical connection, or for electrical test. The pattern 61e to be tested includes a plurality of portions 612e to be tested. The portions 612e to be tested are bonding pads or electrical contacts, protrude from one surface of the body 60e, and are spaced from each other or separated from each other. A pitch P₅ is formed between the portions 612e to be tested in the x-direction in the figure, and the pitch P₅ is substantially uniform, single or consistent. The pitch P₅ is defined as the distance between the geometric centers of the portions 612e to be tested. In one embodiment, the pitch P₅ is 6000 μm.

The disclosure further relates to a testing method, including the following steps.

Firstly, a plurality of elements to be tested are provided. The elements to be tested include different patterns to be tested, and each pattern to be tested includes a plurality of portions to be tested. For example, as shown in FIG. 5, FIG. 5E, FIG. 6, FIG. 7 and FIG. 8, a plurality of elements 6a, 6b, 6c, 6d to be tested and an apparatus 6′ to be tested (or an element to be tested) are provided. The elements 6a, 6b, 6c, 6d to be tested have different patterns 61a, 61b, 61c. 61d to be tested, and each pattern to be tested has a plurality of portions 611a, 612a, 611b, 612b, 611c, 612c, 631, 632 to be tested.

Then, an universal probe card is provided. The universal probe card includes a probe holder and a plurality of probes. The probe holder defines a plurality of accommodating holes. The pitch between the accommodating holes is determined by the pitch between the portions to be tested in the different patterns to be tested. At least one group of the probes are respectively located in at least one group of the accommodating holes. For example, as shown in FIG. 1 to FIG. 4A, a universal probe card 1 is provided. The universal probe card 1 includes a probe holder 3 and a plurality of probes 2. The probe holder 3 defines a plurality of accommodating holes 34. The pitch P″ between the accommodating holes 34 is determined by the pitches between the portions 611a, 612a, 611b, 612b, 611c, 612c, 631, 632 to be tested of the different patterns 61a, 61b, 61c, 61d to be tested, and at least one group of the probes 2 are respectively located in at least one group of the accommodating holes 34.

The pitch P′ between the probes 2 and the pitch P″ between the accommodating holes 34 are a greatest common factor of the pitches (for example, a pitch P″ of FIG. 5H, a pitch P₂ of FIG. 6C, a pitch P₃ of FIG. 7C, and a pitch P₄ of FIG. 8) between the portions to be tested (for example, the portions 611a, 612a to be tested of FIG. 5, the portions 611a, 612a to be tested of FIG. 5E, the portions 611b, 612b to be tested of FIG. 6, the portions 611c, 612c to be tested of FIG. 7, and the portions 631, 632 to be tested of FIG. 8) in the different patterns to be tested (for example, the pattern 61a to be tested of FIG. 5, the pattern 61a to be tested of FIG. 5E, the pattern 61b to be tested of FIG. 6, the pattern 61c to be tested of FIG. 7 and the pattern 61d to be tested of FIG. 8). That is, at least one part or at least one group of the probes 2 are distributed corresponding to the portions to be tested in the patterns to be tested of at least one of the elements 6a, 6′, 6b, 6c, 6d to be tested. In one embodiment, the probes 2 are plugged/unplugged (or inserted/pulled) according to the portions to be tested in the patterns to be tested of at least one of the elements 6a, 6′, 6b, 6c, 6d to be tested.

Then, at least one of the elements to be tested is contacted by using at least one group of the probes. For example, as shown in FIG. 5D, FIG. 6D, FIG. 7D and FIG. 8A, at least one group or at least one part of the probes 2 contacts at least one of the elements 6a, 6b, 6c, 6d to be tested, so as to perform a test process.

The foregoing embodiments are merely illustrative of the principles and effects of the disclosure, and are not to be construed as limiting the disclosure. Thus, those skilled in the art will appreciate that various modifications and changes can be made to the above embodiments without departing from the spirit of the disclosure. The scope of the disclosure is to be determined by the following claims. Moreover, the scope of the application is not intended to be limited to the particular embodiments described in the specification. A person of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the disclosure.

What is claimed is:

1. An universal probe card, comprising:
a plurality of probes, configured to contact and test a plurality of different patterns to be tested, wherein each of the plurality of different patterns to be tested includes a plurality of portions to be tested, and a pitch between the plurality of probes is a greatest common factor of pitches between the plurality of portions to be tested in the plurality of different patterns to be tested.

2. The universal probe card according to claim 1, wherein the plurality of probes are arranged in an array, and have a single pitch.

3. The universal probe card according to claim 1, wherein the plurality of probes are arranged in a staggered manner.

4. The universal probe card according to claim 1, wherein the plurality of probes comprise a plurality of first probes and a plurality of second probes, the plurality of first probes are arranged in an array, and wherein one of the plurality of second probes is located at a central point of four of the plurality of first probes closest to the one of the plurality of second probe.

5. The universal probe card according to claim 4, wherein all of the plurality of first probes have a single pitch.

6. The universal probe card according to claim 1, wherein the plurality of patterns to be tested are respectively located on a plurality of separated elements to be tested, and the plurality of portions to be tested are bonding pads or bumps.

7. The universal probe card according to claim 1, wherein the plurality of patterns to be tested are located on a same apparatus to be tested, and the plurality of portions to be tested are bonding pads or bumps.

8. An universal probe card, configured to test a plurality of different elements to be tested, and comprising:
a probe holder, defining a plurality of accommodating holes, wherein a pitch between the plurality of accommodating holes is a greatest common factor of pitches between a plurality of portions to be tested of the plurality of different elements to be tested.

9. The universal probe card according to claim 8, further comprising:
a plurality of probes, configured to contact the plurality of elements to be tested, wherein at least one group of the plurality of probes are respectively located in at least one group of the plurality of accommodating holes.

10. The universal probe card according to claim 9, wherein the plurality of probes are disposed in all of the plurality of accommodating holes.

11. The universal probe card according to claim 9, wherein the plurality of probes are not disposed in all of the plurality of accommodating holes.

12. The universal probe card according to claim 8, wherein the plurality of accommodating holes are arranged in an array, and have a single pitch.

13. The universal probe card according to claim 8, wherein the plurality of accommodating holes are arranged in a staggered manner.

14. The universal probe card according to claim 8, wherein the plurality of accommodating holes comprise a plurality of first accommodating holes and a plurality of second accommodating holes, the plurality of first accommodating holes are arranged in an array, and one of the plurality of second accommodating holes is located at a central point of four of the plurality of accommodating holes closest to the one of the plurality of second accommodating holes.

15. The universal probe card according to claim 14, wherein all of the plurality of first accommodating holes have a single pitch.

16. The universal probe card according to claim 8, wherein the plurality of elements to be tested are a plurality of separated elements, and the plurality of portions to be tested are bonding pads or bumps.

17. The universal probe card according to claim 8, wherein the plurality of elements to be tested are located on a same apparatus to be tested, and the plurality of portions to be tested are bonding pads or bumps.

18. The universal probe card according to claim 8, wherein the plurality of accommodating holes extend through the probe holder.

19. The universal probe card according to claim 18, wherein each of the plurality of accommodating holes includes a first portion and a second portion, and a width of the first portion is different from a width of the second portion.

20. The universal probe card according to claim 19, wherein the width of the first portion is less than the width of the second portion, and a part of a probe is inserted in and fixed to the first portion.

21. The universal probe card according to claim 19, wherein the width of the first portion is less than the width of the second portion, and a part of a probe is inserted in the first portion and is withdrawable.

22. The universal probe card according to claim 9, further comprising:
a circuit board, configured to be connected to the plurality of probes for electrical test.

23. A testing method, comprising:
providing a plurality of elements to be tested, wherein the plurality of elements to be tested have a plurality of different patterns to be tested, and each of the plurality of patterns to be tested has a plurality of portions to be tested;
providing an universal probe card, wherein the universal probe card comprises a probe holder and a plurality of probes, the probe holder defines a plurality of accommodating holes, a pitch between the plurality of accommodating holes is determined by the pitches between the plurality of portions to be tested in the plurality of different patterns to be tested, and at least one group of the plurality of probes are respectively located in at least one group of the plurality of accommodating holes; and
contacting at least one of the plurality of elements to be tested by using the at least one group of the plurality of probes.

24. The testing method according to claim 23, wherein the pitch between the plurality of accommodating holes is a greatest common factor of the pitches between the plurality of portions to be tested of the plurality of different elements to be tested.

25. The testing method according to claim 23, wherein the plurality of accommodating holes are arranged in an array.

26. The testing method according to claim 23, wherein the at least one group of the probes are distributed corresponding to the plurality of portions to be tested of the plurality of patterns to be tested of at least one of the plurality of elements to be tested.

27. The testing method according to claim 23, wherein providing the universal probe card further comprises:
plugging/unplugging the plurality of probes according to the plurality of portions to be tested in the plurality of patterns to be tested of at least one of the plurality of elements to be tested.
